(19) United States
(12) Patent Application Publication
(10) Pub. No.: US 2025/0004014 A1
(43) Pub. Date: Jan. 2, 2025

(54) MULTIPLE PULSE EXTRACTION FOR TRANSMITTER CALIBRATION

(71) Applicant: Tektronix, Inc., Beaverton, OR (US)

(72) Inventors: Kan Tan, Portland, OR (US); David M. Bouse, Camas, WA (US); John J. Pickerd, Beaverton, OR (US)

(21) Appl. No.: 18/754,871

(22) Filed: Jun. 26, 2024

Related U.S. Application Data
(60) Provisional application No. 63/548,796, filed on Feb. 1, 2024.
(60) Provisional application No. 63/524,205, filed on Jun. 29, 2023.
(60) Provisional application No. 63/524,204, filed on Jun. 29, 2023.

(51) Int. Cl. G01R 13/02; G01R 31/28; G01R 31/317

(52) U.S. Cl. CPC G01R 13/0272; G01R 31/2834; G01R 31/31709

(57) ABSTRACT

A test and measurement instrument has a port to receive a signal from a device under test (DUT), one or more processors configured to execute code that causes the one or more processors to acquire a waveform from the signal, derive a pattern waveform from the waveform using one of either hardware or software clock recovery, perform linear fit pulse response (LFPR) extractions on the pattern waveform to extract more than one LFPR, determine a reference pulse response from the more than one LFPRs, compare at least one of the LFPRs to the reference pulse response to determine a difference, and tune the DUT to reduce the difference. The test and measurement instrument may also use the multiple LFPRs as an input to a machine learning network to perform measurement predictions for the DUT.

### RELATED APPLICATIONS

This disclosure is a non-provisional of and claims benefit from U.S. Provisional Application No. 63/525,204, titled “MULTIPLE PULSE EXTRACTION FOR TRANSMITTER CALIBRATION,” filed Jun. 29, 2023, U.S. Provisional Application No. 63/524,205, titled, “MACHINE LEARNING BASED MEASUREMENT USING MULTIPLE EXTRACTED PULSES,” filed Jun. 29, 2023, and U.S. Provisional Application No. 63/548,796, titled, “MULTIPLE-PULSES-BASED DECISION FEEDBACK EQUALIZER (MPDFE),” filed Feb. 1, 2024, the disclosures of which are incorporated herein by reference in their entirety.

### TECHNICAL FIELD

This disclosure relates to test and measurement instruments and methods, and more particularly to multiple pulse extraction and its use in transmitter calibration, measurements, and equalizers.

### BACKGROUND

As the speed of signals increases as the next generation of high-speed communication systems are designed and employed, the signal integrity requirements become increasingly stringent. The timing budget decreases as the bit rate increases causing the unit interval (UI) to decrease. The vertical eye margin is reduced by three times when the signaling scheme changes from NRZ (Non-return-to-zero) to PAM4 (pulse amplitude modulation 4). Improving the communication link performance requires accurate transmitter calibration. For PAM4 electrical signaling, the transmitter is characterized by the measurement of SNDR (Signal-to-Noise-and-Distortion Ratio). The best transmitter calibration results in highest possible SNDR for the transmitter. SNDR has become the key measurement that characterizes the transmitters in the high-speed serial standards including PCIE (Peripheral Component Interconnect Express) Gen 6 and Gen7, 400 Gb/s Ethernet IEEE 802.3cd and IEEE 802.3ck, all available at http://www.ieee802.org/3/, and hereby incorporated by reference in their entirety.

The SNDR measurement is defined as:

$$SNDR = 10 \times {log}_{10} ( \frac{{p}_{max}^{2}}{{σ}_{e}^{2} + {σ}_{n}^{2}} ) \qquad ( 1 )$$

Where pₘₐₓ represents the “signal” term in the SNDR and is defined as the peak value of the extracted linear fit pulse response (LFPR). σₑ represents the “distortion” term in the SNDR and is defined as the fitting error of the linear fit. σₙ represents the “noise” term in the SNDR and is defined as the vertical noise.

The extracted LFPR has other uses as well. U.S. patent application Ser. No. 18/210,583, “EXTRACTED LINEAR FIT PULSE RESPONSE BASED MACHINE LEARNING FOR MEASUREMENT,” filed Aug. 21, 2022, discusses using LFPR and other data representations of waveforms provided to a machine learning network to predict measurements for waveforms received from a device under test (DUT). The contents of this application are incorporated by reference herein in its entirety. Improving the speed and accuracy of these predictions would have many benefits.

### BRIEF DESCRIPTION OF THE DRAWINGS

FIG. 1 shows an embodiment of a test and measurement device.

FIG. shows an eye diagram of a PAM4 waveform.

FIG. 3 shows a pattern waveform of the PAM4 waveform of FIG. 2.

FIG. 4 shows a full view of a single extracted linear fit pulse response (LFPR) from the pattern waveform of FIG. 3.

FIG. 5 shows a full view and a zoomed in view of an embodiment of extracted even and odd LFPRs and the difference between them.

FIG. 6. shows four normalized LFPRs for four symbols.

FIG. 7 shows the un-normalized LFPRs of FIG. 6.

FIG. 8 shows full and zoomed views of eight normalized LFPRs.

FIG. 9 shows one LFPR compared to an average LFPR and the difference.

FIG. 10 shows an example of a PAM4 pattern waveform.

FIG. 11 shows an eye diagram for the PAM4 pattern waveform of FIG. 10.

FIG. 12 shows a single pulse extracted from the pattern waveform of FIG. 10.

FIG. 13 shows four un-normalized linear fit pulse responses (LFPR) for the pattern waveform of FIG. 10.

FIG. 14 shows the normalized four LFPRs from FIG. 10.

FIG. 15 shows a vertical histogram of the waveform of FIG. 10.

FIG. 16 shows a two-dimensional image prepared for submission into a machine learning network from the pattern waveform of FIG. 10.

FIG. 17 shows two-dimensional images prepared for submission into a machine learning network for four different signals having different LFPRs and vertical histograms.

FIG. 18 shows an embodiment of a convolutional neural network that can use multiple pulses.

FIG. 19 shows an embodiment of an eye diagram with identified vertical and horizontal histogram locations.

FIG. 20 shows an example of a traditional decision feedback equalizer (DFE) structure.

FIG. 21 shows an embodiment of a multiple pulse-based decision feedback equalizer (MPDFE) structure.

FIG. 22 shows a diagram of an embodiment of an MPDFE tap value selection based upon a symbol at a delay line position.

FIG. 23 shows a PAM4 pattern waveform.

FIG. 24 shows a PAM4 eye diagram.

FIG. 25 shows a single LFPR from the waveform of FIG. 23.

FIG. 26 shows a comparison of a LFPR and the LFPR after application of a traditional DFE.

FIG. 27 shows four un-normalized LFPRs from the pattern waveform of FIG. 23.

FIG. 28 shows four normalized LFPRs from FIG. 27.

FIG. 29 shows results of PAM4 symbol 2 and symbol 3 after application of a traditional DFE.

FIG. 30 shows results of PAM4 symbol 2 and symbol 3 after application of a MPDFE.

FIG. 31 shows an eye diagram of the PAM4 pattern waveform of FIG. 23 after application of a traditional DFE.

FIG. 32 shows an eye diagram of the PAM4 pattern waveform of FIG. 23 after application of a MPDFE.

### DETAILED DESCRIPTION

The embodiments here involve a new technique that extracts multiple pulses instead of one single pulse from signals produced by a device under test (DUT) or a communication device. In one embodiment the DUT comprises a transmitter and the embodiments use multiple pulses to calibrate the transmitter to optimize the SNDR value. The embodiments focus on the linear fit pulse response related terms, in particular, ae, the distortion term of SNDR discussed above.

Multiple pulse extraction uses some of the same definitions and operations for single LFPR, so the discussion starts there. The IEEE standard 802.3ba referenced above discusses single pulse extraction. As used here, the terms “pulse,” pulse response,” and “linear fit pulse response (LFPR),” all refer to the resulting pulse shown in several figures. Pulse responses, single one or multiple ones, result from the process of linear fitting. Linear fit is the method to obtain the pulse(s). Since fitting allows the obtaining of the pulse(s) from the pattern waveform, one could say that the fitting extracts pulse(s) from the pattern waveform.

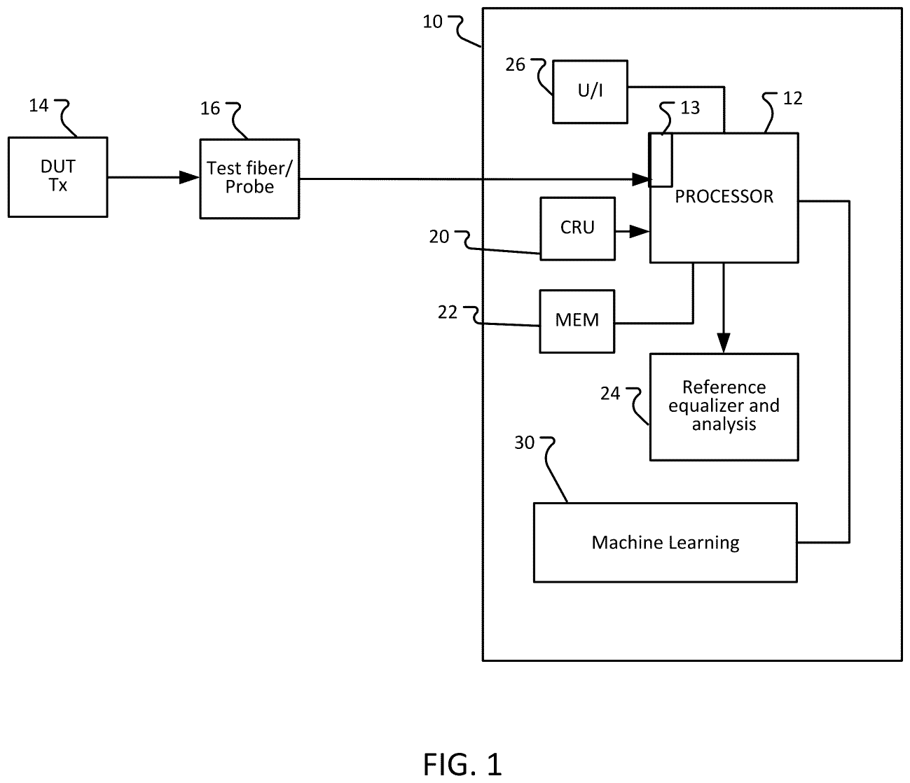

A device under test (DUT) generates a waveform that a test and measurement instrument captures. FIG. 1 shows an embodiment of such an instrument. FIG. 1 shows an embodiment of a testing setup in the instance of the test and measurement instrument measuring or testing the DUT 14. The testing setup may include a test and measurement instrument such as an oscilloscope 10. The test and measurement instrument 10 receives a signal from the DUT 14 directly or through an instrument probe 16. In the case of an optical transmitter DUT, the probe will typically comprise a test fiber coupled to an optical to electrical converter, not shown, that provides a signal to the test and measurement instrument through one or more ports 13. Two ports may be used for differential signaling, while one port is used for single-ended signaling. The signals are sampled and digitized by the instrument to become waveforms. A clock recovery unit (CRU) 20 may recover the clock signal from the data signal if the test and measurement instrument 10 comprises a sampling oscilloscope for example. A software clock recovery can be used on a real-time oscilloscope.

The test and measurement instrument has one or more processors represented by processor 12, a memory 22 and a user interface 26. The memory may store executable instructions in the form of code that, when executed by the processor, causes the processor to perform tasks. User interface 26 of the test and measurement instrument allows a user to interact with instrument 10, such as to input settings, configure tests, etc. The test and measurement instrument may also include a reference equalizer and analysis module 24.

The embodiments here employ machine learning in the form of a machine learning network 30, such a deep learning network. The machine learning network may include a processor that has been programmed with the machine learning network as either part of the test and measurement instrument, or to which the test and measurement instrument has access. As test equipment capabilities and processors evolve, the one or more processors such as 12 may include both. The machine learning system may take the form of programmed models operating on one or more of the processors.

The process of extracting a single LFPR is as follows. When a waveform is captured from a DUT, the instrument can re-sample the acquired waveform to have M samples per UI (unit interval) using hardware or software clock recovery. The resampled and averaged pattern waveform is denoted as y(k). The symbols x(n) is aligned with y(k) such that the first M samples of y(k) correspond to the first symbol of the test pattern x(n), the second M samples of y(k) to the second symbol, and so on. If the pattern length is N, the M-by-N, waveform matrix Y is defined as

$$Y = [ \begin{matrix}y ( 1 ) & y ( M + 1 ) & … & y ( M ( N - 1 ) + 1 ) \\ y ( 2 ) & y ( M + 2 ) & … & y ( M ( N - 1 ) + 2 ) \\ … & … & … & … \\ y ( M ) & y ( 2 M ) & … & y ( MN )\end{matrix} ] \qquad ( 2 )$$

The process then rotates the symbols vector x by the specified pulse delay Dₚ to yield a delayed symbols vector, xᵣ, as shown in Equation (3)

$${x}_{r} = [ \begin{matrix}x ( {D}_{p} + 1 ) & x ( {D}_{p} + 2 ) & … & x ( N ) x ( 1 ) & … & x ( N - {D}_{p} )\end{matrix} ] \qquad ( 3 )$$

Dₚ is the pulse delay in terms of unit intervals (UI). The pulse delay dictates how many pre-cursors are included in the extract pulse. Nₚ is the length of the pulse in terms of UIs. If Nₚ equals 600, the extract pulse covers 600 UIs.

Define the symbols matrix X to be an N-by-N symbol matrix derived from xᵣ as shown in Equation (4)

$$X = [ \begin{matrix}{x}_{r} ( 1 ) & {x}_{r} ( 2 ) & … & {x}_{r} ( N ) \\ {x}_{r} ( N ) & {x}_{r} ( 1 ) & … & {x}_{r} ( N - 1 ) \\ … & … & … & … \\ {x}_{r} ( 2 ) & {x}_{r} ( 3 ) & … & {x}_{r} ( 1 )\end{matrix} ] \qquad ( 4 )$$

Define the subset symbols matrix X₁ to be the first Nₚ rows of X concatenated with a row vector of ones of length N. The M-by-(Nₚ+1) coefficient matrix, P, corresponding to the linear fit pulse response is then defined by Equation (5). The superscript “T” denotes the matrix transpose operator.

$$P = {{YX}_{1}^{T} ( {X}_{1} {X}_{1}^{T} )}^{- 1} \qquad ( 5 )$$

The error waveform, e(k), is then read column-wise from the elements of E as shown in Equation (6)

$$E = {PX}_{1} - Y = [ \begin{matrix}e ( 1 ) & e ( M + 1 ) & … & e ( M ( N - 1 ) + 1 ) \\ e ( 2 ) & e ( M + 2 ) & … & e ( M ( N - 1 ) + 2 ) \\ … & … & … & … \\ e ( M ) & e ( 2 M ) & … & e ( MN )\end{matrix} ] \qquad ( 6 )$$

The distortion term, also called fitting error, σₑ, is defined as the root mean squared (RMS) value of the error waveform e(k).

Define P₁ to be a subset coefficient matrix consisting of the first Nₚ columns of the matrix P as shown in Equation (7). The linear fit pulse response, p(k), is then read column-wise from the elements of P₁.

$${P}_{1} = [ \begin{matrix}p ( 1 ) & p ( M + 1 ) & … & p ( M ( {N}_{p} - 1 ) + 1 ) \\ p ( 2 ) & p ( M + 2 ) & … & p ( M ( {N}_{p} - 1 ) + 2 ) \\ … & … & … & … \\ p ( M ) & p ( 2 M ) & … & p ( {MN}_{p} )\end{matrix} ] \qquad ( 7 )$$

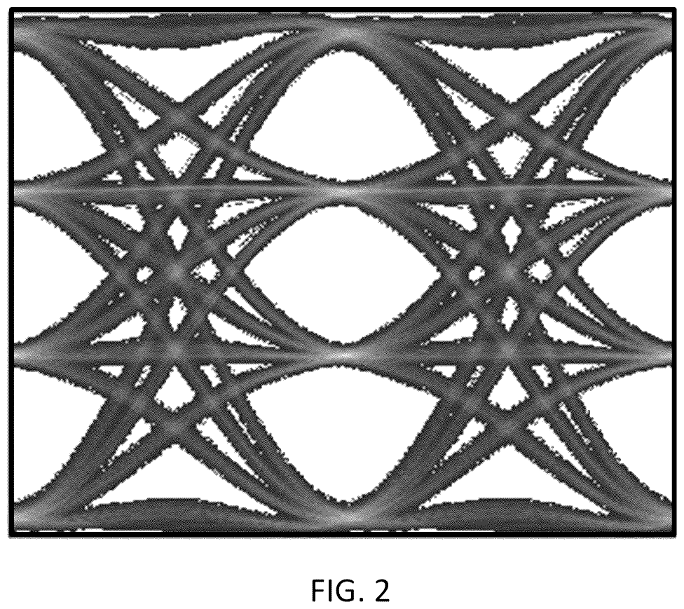

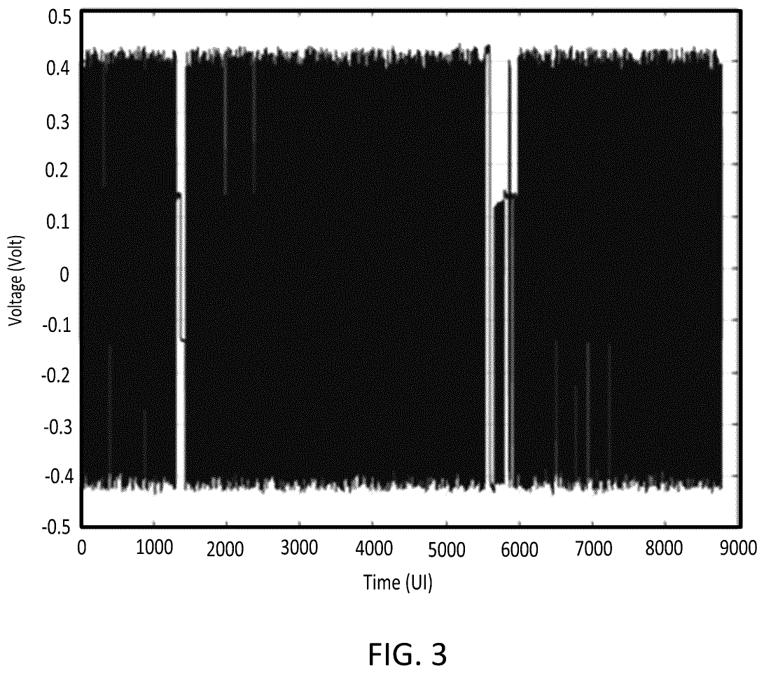

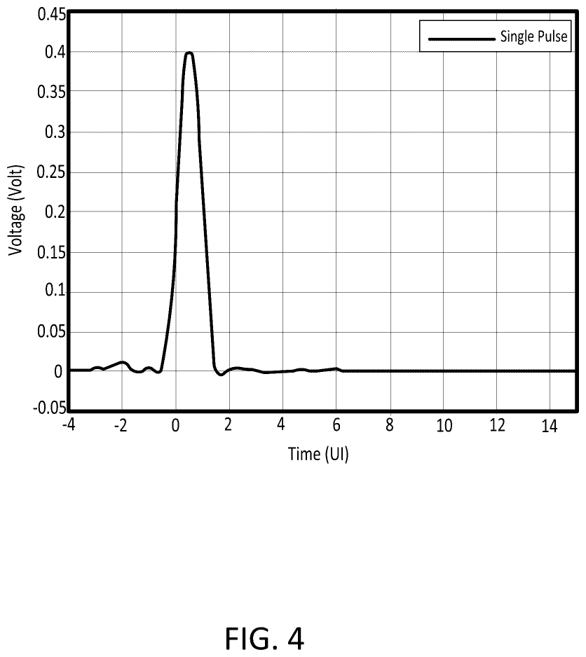

For a PAM4 signal which has an eye diagram shown in FIG. 2 and the averaged pattern waveform shown in FIG. 3, the single pulse extracted using the current linear fit pulse response extraction method is shown in FIG. 4. For a PAM4 signal, the symbol 0, 1, 2, 3 are represented as value of [−1 −⅓ ⅓ 1] in symbol vector x.

Instead of the conventional technique of using a single pulse to fit to the pattern waveform, embodiments herein use multiple pulses to fit to the pattern waveform. Various examples of multiple pulses, according to various embodiments of the disclosure are discussed.

The process may use even and odd pulses. The two pulses represent the pulse at even UI and odd UI. The process can use this model to find the difference between the even and odd pulses caused by the duty cycle error, also called the even odd jitter, where the timing differs between the even and odd UIs. To maintain the even and odd sequence, if the pattern length is an odd number, then two times of the odd pattern length is used to calculate the averaged pattern waveform y(k) and the aligned symbols x(n). The pattern length used to calculate the even and odd pulses is doubled over the original odd pattern length. If the original pattern has an even length, then the process uses the original pattern length to calculate even and odd pulses.

To get the two pulses representing the even and odd pulses, define X_{N}_{ₚ} to be the first Nₚ rows of X in Equation (4). Further, the process defines the following two Nₚ-by-N switch matrices for even and odd pulses.

The switch matrix turns on and off the elements in another matrix when the two matrices are combined with dot product. “Turn on” an element means the element value is preserved, “turn off” an element means the element is set to 0.

The switch matrix for the odd UI is defined as:

$${W}_{odd} = [ \begin{matrix}1 & 0 & 1 & … \\ 0 & 1 & 0 & … \\ 1 & 0 & 1 & … \\ … & … & … & …\end{matrix} ] \qquad ( 8 )$$

where its first row starts with 1 and alternates between 0 and 1. The second row starts with 0 and alternates between 0 and 1, and so on. The switch matrix Wₑᵥₑₙ for the even UI is defined in Equation (9), it is complementary to W_{odd}.

$${W}_{even} = [ \begin{matrix}0 & 1 & 0 & … \\ 1 & 0 & 1 & … \\ 0 & 1 & 0 & … \\ … & … & … & …\end{matrix} ] \qquad ( 9 )$$

Denote

$${X}_{even \_ odd} = [ \begin{matrix}{X}_{{N}_{p}} \cdot {W}_{odd} \\ {X}_{{N}_{p}} \cdot {W}_{even} \\ ones ( 1 , N )\end{matrix} ] \qquad ( 10 )$$

where “⋅“denotes the dot product operator, and ones(1,N) denotes a row vector of ones of length.

Calculate the following equation to get P_{even_odd}

$${P}_{even \_ odd} = {{YX}_{evn \_ odd}^{T} ( {X}_{evn \_ odd} {X}_{evn \_ odd}^{T} )}^{- 1} \qquad ( 11 )$$

and the fitting error

$${E}_{even \_ odd} = {P}_{even \_ odd} \cdot {X}_{even \_ odd} - Y \qquad ( 12 )$$

Let P_{odd} be the first Nₚ columns of P_{even_odd} and Pₑᵥₑₙ be the next Nₚ columns of P_{even_odd}, then the linear fit pulse response for the odd UI, p_{odd}(k), is then read column-wise from the elements of P_{odd}. The linear fit pulse response for the even UI, Pₑᵥₑₙ(k), is read column-wise from the elements of Pₑᵥₑₙ.

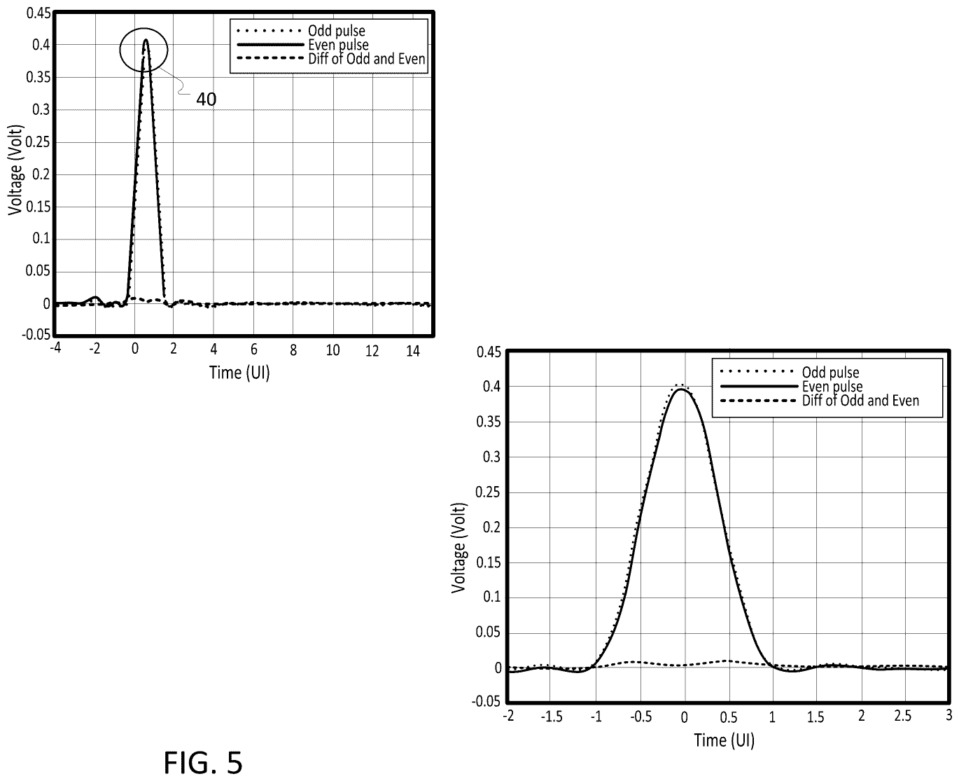

For the waveform shown in FIG. 3, FIG. 5 shows the even pulse, odd pulse, and their difference obtained using this procedure in both full view and zoomed in view. The zoomed in view on the right shows a little more detail of the difference between the even pulse and the odd pulse, especially noticeable at the peak of the pulse response shown by circle 40 in the full view.

A PAM4 signal has 4 symbols, symbol 0, 1, 2, 3. To check the linearity, the levels of symbols 0 and 3 are commonly used as the reference levels, then check whether the levels of symbols 1 and 2 are evenly spaced between the reference levels. For the multiple pulses extraction for PAM4 symbols, three pulses are extracted: one normalized pulse representing both symbol 0 and symbol 3, one normalized pulse for symbol 1 and one normalized pulse for symbol 2. The process defines the following three Nₚ-by-N switch matrices for the three normalized pulses as

$${W}_{sym 0 \_ 3} = ( {X}_{{N}_{p}} == - 1 ) or ( {X}_{{N}_{p}} == 1 ) \qquad ( 13 )$$

$${W}_{sym 1} = ( {X}_{{N}_{p}} == - 1 / 3 )$$

$${W}_{sym 2} = ( {X}_{{N}_{p}} == 1 / 3 )$$

Where the “==” operation returns a Boolean value. If the Boolean value in an element in the matrix is true where the “==” condition is satisfied, then the corresponding element in W_{sym} is set to 1. If the Boolean value is false where the “==” condition is not satisfied, the element in W_{sym} is set to 0.

Denote

$${X}_{sym} = [ \begin{matrix}{X}_{{N}_{p}} \cdot {W}_{sym 0 \_ 3} \\ {X}_{{N}_{p}} \cdot {W}_{sym 1} \\ {X}_{{N}_{p}} \cdot {W}_{sym 2} \\ ones ( 1 , N )\end{matrix} ] \qquad ( 14 )$$

Calculate the following equation to get P_{sym}

$${P}_{sym} = {{YX}_{sym}^{T} ( {X}_{sym} {X}_{sym}^{T} )}^{- 1} \qquad ( 15 )$$

And the fitting error

$${E}_{sym} = {P}_{sym} \cdot {X}_{sym} - Y \qquad ( 16 )$$

Let P_{sym0_3} be the first Nₚ columns of P_{sym}, then P_{sym1} be the next Nₚ columns of P_{sym}, and P_{sym2} be the next Nₚ columns. The normalized linear fit pulse response for the symbol 0 and symbol 3, P_{sym0_3}(k), is then read column-wise from the elements of P_{sym0_3}. The normalized linear fit pulse response for symbol 1, p_{sym1}(k), is read column-wise from the elements of P_{sym1}. The normalized linear fit pulse response for symbol 2, P_{sym2} (k), is read column-wise from the elements of P_{sym2}.

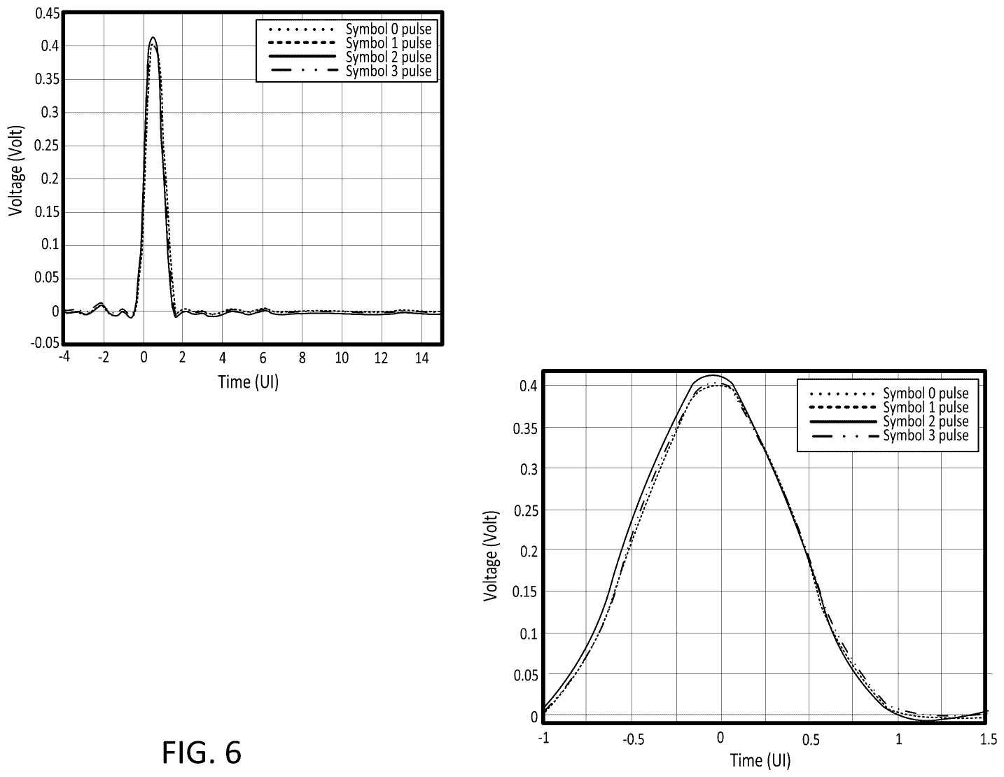

FIG. 6 shows the full view and a zoomed in version of the multiple pulses extracted from the waveform shown in FIG. 3. One can see the differences between the symbols in the zoomed in version to the right, with the symbol 1 pulse almost overlaying completely on the symbol 3 pulse.

The normalized pulses for all symbols are like each other as shown in FIG. 6, making it easier to compare the pulses in the same scale. Normalized pulses can be un-normalized.

$${p}_{sym 0 \_ un \_ normalized} = - {p}_{sym 0 \_ 3} \qquad ( 17 )$$

$${p}_{sym 1 \_ un \_ normalized} = - \frac{1}{3} {p}_{sym 1}$$

$${p}_{sym 2 \_ un \_ normalized} = \frac{1}{3} {p}_{sym 2}$$

$${p}_{sym 3 \_ un \_ normalized} = {p}_{sym 0 \_ 3}$$

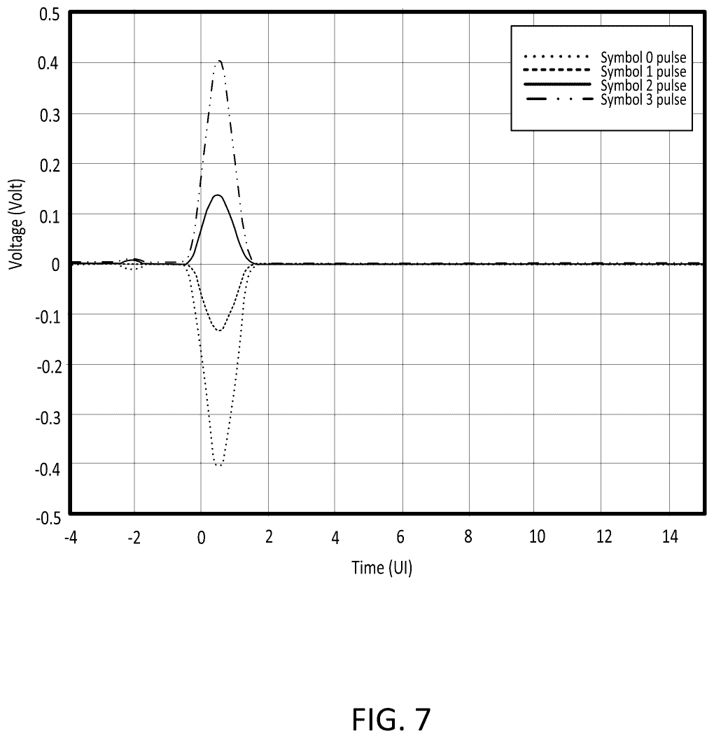

FIG. 7 shows the un-normalized pulses.

More details of the PAM4 signal can be obtained by fitting multiple pulses for the PAM4 symbols at even and odd UI. It is a combination of the even and odd pulse embodiment, and the four pulses embodiment described above. In this embodiment, each of the PAM4 symbols is represented by two pulses, one for odd UI, and one for even UI. As the levels of symbols 0 and 3 are commonly used as the reference levels, allowing one to check whether the levels of symbols 1 and 2 are evenly spaced between the reference levels. For the multiple pulse extraction for PAM4 symbols at even and odd UI, six pulses are extracted: one normalized pulse representing both symbol 0 and symbol 3 for odd UI and one for even UI, one normalized pulse for symbol 1 for odd UI and one for even UI, one normalized pulse for symbol 2 for odd UI and one for even UI. Defines the following six Nₚ-by-N switch matrices for the six pulses as

$${W}_{sym 0 \_ 3 \_ odd} = {W}_{sym 0 \_ 3} \cdot {W}_{odd} \qquad ( 18 )$$

$${W}_{sym 0 \_ 3 \_ even} = {W}_{sym 0 \_ 3} \cdot {W}_{even}$$

$${W}_{sym 1 \_ odd} = {W}_{sym 1} \cdot {W}_{odd}$$

$${W}_{sym 1 \_ even} = {W}_{sym 1} \cdot {W}_{even}$$

$${W}_{sym 2 \_ odd} = {W}_{sym 2} \cdot {W}_{odd}$$

$${W}_{sym 2 \_ even} = {W}_{sym 2} \cdot {W}_{even}$$

where the switch matrices at the right side as the equations are defined in the first two cases of multiple pulses.

Denote

$${X}_{sym \_ even \_ odd} = [ \begin{matrix}{W}_{sym 0 \_ 3 \_ odd} \\ {W}_{sym 0 \_ 3 \_ even} \\ {W}_{sym 1 \_ odd} \\ {W}_{sym 1 \_ even} \\ {W}_{sym 2 \_ odd} \\ {W}_{sym 2 \_ even} \\ ones ( 1 , N )\end{matrix} ] \qquad ( 19 )$$

Calculate the following equation to get P_{sym_even_odd}

$${P}_{sym \_ even \_ odd} = {{YX}_{sym \_ even \_ odd}^{T} ( {X}_{sym \_ even \_ odd} {X}_{sym \_ even \_ odd}^{T} )}^{- 1} \qquad ( 20 )$$

And the fitting error

$${E}_{sym \_ even \_ odd} = {P}_{sym \_ even \_ odd} \cdot {X}_{sym \_ even \_ odd} - Y \qquad ( 21 )$$

Let P_{sym0_3_odd} be the first Nₚ columns of P_{sym_even_odd}, then P_{sym0_3_even} be the next Nₚ columns of P_{sym_even_odd}, and so on for P_{sym1_odd}, P_{sym1_even}, P_{sym2_odd}, P_{sym2_even}. The normalized linear fit pulse response for the symbol 0 and symbol 3 for odd UI, P_{sym0_3_odd} (k), is then read column-wise from the elements of P_{sym0_3_odd}. The normalized linear fit pulse response for the symbol 0 and symbol 3 for even UI, P_{sym0_3_even}(k), is read column-wise from the elements of P_{sym0_3_even}, and so on for the remaining four pulses.

The matrices X_{even_odd} in Equation 10, X_{sym} in Equation 14, and X_{sym_even_odd} in Equation 19 are referred to as “extended symbol” matrices. They are based upon the symbol matrix, X, and the various switch matrices. Similarly, the various P matrices relate to the coefficient matrix P.

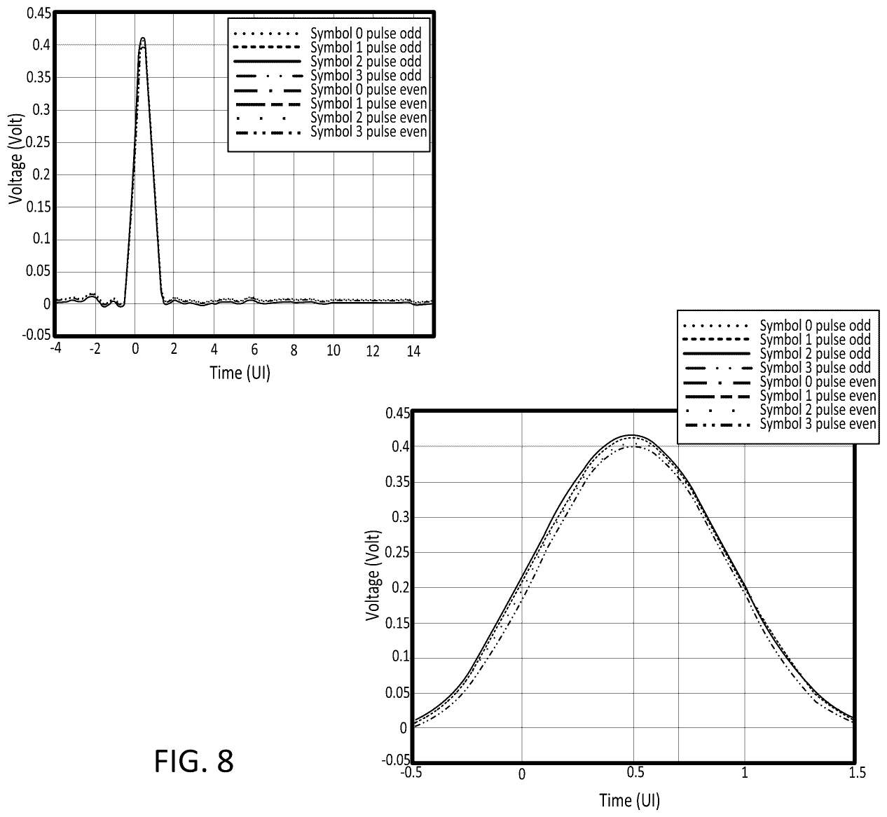

FIG. 8 shows the normalized symbol pulses for even and odd UI obtained for the waveform in FIG. 3 in a full view and a zoomed in view.

In one embodiment, a multiple pulse linear fitting process begins with acquiring the waveform from the DUT, which may be a transmitter. The process then performs either software or hardware clock recovery. It then calculates the averaged data pattern waveform, such as that shown in FIG. 3. The instrument then may get the data pattern sequence through pattern detection, or it may have obtained the known pattern sequence. This allows alignment between the pattern sequence and the pattern waveform.

The process then constructs the symbols matrix, X_{N}_{ₚ}, and the waveform matrix, Y, based on the data pattern sequence and the pattern waveform. This is followed by construction of the switch matrices for the multiple pulse fitting, and the matrices for the fitting solution based on the X_{N}_{ₚ} and the switch matrices. The process then calculates the coefficient matrix, P, that contains pulses information, and the error matrix E. The pulse samples, P_{pulse_i}(k), are read from the matrix, P, and the error waveform e(k) from the matrix, E.

The fitting errors for the waveform shown in FIG. 2 using single pulse vs multiple pulses, as well as the (averaged) pulse peak value are summarized in Table 1.

TABLE 1
Fitting error comparisons

| Method | δₑ(mV) | pₘₐₓ(mV) |
|---|---|---|
| Single pulse | 5.67 | 402.60 |
| Even/odd pulses | 4.43 | 402.60 |
| 4 pulses for 4 symbols | 4.97 | 402.61 |
| 8 pulses for 4 symbols & even/odd | 3.35 | 402.61 |

Note that multiple pulse fitting reveals the difference among the normalized pulses. When the fitting allows using multiple pulses, the fitting error de is reduced. The (averaged) pₘₐₓ values are almost the same for single pulse fitting and multiple pulse fitting.

When there are mismatches among the multiple pulses, the single pulse fitting yields a larger fitting error than the multiple pulse fitting. Larger fitting error comprises a penalty on the transmitter measurement such as SNDR. To improve the transmitter performance, the multiple pulse fitting can be used as a tool to calibrate the transmitter so that the multiple pulses are better matched.

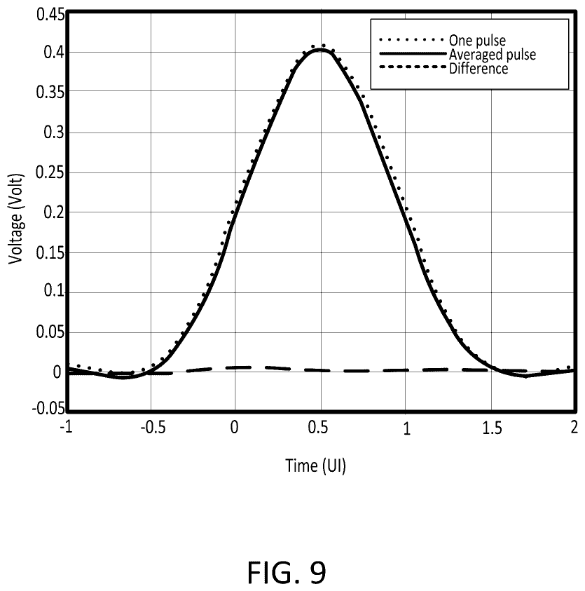

As shown in FIG. 9, the averaged pulse comprises the average of all the pulses to be calibrated. For example, the averaged pulse could be the average of the even pulse and the odd pulse. Each pulse is compared against the averaged pulse, any non-zero difference, as shown in the plot, represents the mismatch.

An example transmitter calibration process, according to some embodiments of the disclosure, is described as follows. The test and measurement instrument acquires the waveform from the transmitter. The one or more processors then perform the multiple pulse fitting discussed above. The choice of the pulses depends on the transmitter characteristics and calibration goals. For example, if the transmitter has even and odd timing error, the even odd pulse fitting can be selected. The process then calculates the averaged pulse. The average pulse is calculated using the normalized pulses. Tuning the transmitter involves selecting one or several normalized pulses, comparing them against the averaged pulse, and then tuning the transmitter to reduce the difference. This process may repeat until the mismatch between the pulses is minimized.

Instead of using the averaged pulse, two or more normalized pulses may be compared directly. To encompass both options, the averaged pulse comprises an embodiment of a reference pulse. When two normalized pulses are compared directly, one of the normalized pulses would act as the reference pulse.

Transmitter calibration may use various types of multiple pulses. For example, tune the even odd pulse mismatch first to reduce the mismatch between even and odd UI, as set out in the even-odd pulse discussion above, then tune the symbol level linearity mismatch, using the symbols embodiment above. Alternatively, tune the symbols at even and odd UI directly, in the even-odd symbols embodiment above.

This discussion has used PAM4 to describe the multiple pulse fitting processes and the calibration method. The method can be generalized to other PAMn modulation, where n could be other value besides n=4.

Up to this point, the discussion has described a new multiple pulse fitting method that introduces switch matrices for various multiple pulses choices. The multiple pulses fitting, also referred to as multiple pulse extraction, reveals the details of the pulses hidden by the data waveform. The details of the pulses can be used to debug the device as well as used for calibrations. The multiple pulse fitting returns a numerically stable and precise result as the fitting routine uses the full waveform. The calibration can achieve higher precision with the precise multiple pulses obtained from the fitting algorithms.

Having discussed the methodology as to how to perform multiple pulse extraction, one can consider various uses and applications for multiple pulse extraction. This includes using multiple pulses for machine learning for measurement.

U.S. patent application Ser. No. 18/210,583, filed Jun. 15, 2023, titled “MACHINE LEARNING FOR MEASUREMENT USING LINEAR RESPONSE EXTRACTED FROM WAVEFORM,” hereinafter “the '583 application,” the contents of which are hereby incorporated by reference into this disclosure, introduces machine learning based measurement using a single pulse extracted from a waveform. Other forms of data have been considered for machine learning based measurement. For example, the eye diagram of the signal has been used by machine learning to get measurement results. See S. Varughese, A. Melgar, V. A. Thomas, P. Zivny, S. Hazzard and S. E. Ralph, “Accelerating Assessments of Optical Components Using Machine Learning: TDECQ as Demonstrated Example,” Journal of Lightwave Technology, vol. 39, no. 1, pp. 64-72, 2021, hereinafter “Varughese.”

The full or partial pattern waveform are also used for machine learning for measurement. See id. U.S. Pat. App. Pub. No. 2022/0373598, published Nov. 24, 2022, titled “SHORT PATTERN WAVEFORM DATABASE BASED MACHINE LEARNING FOR MEASUREMENT,” hereinafter “the '598 application,” the contents of which are hereby incorporated by reference into this disclosure, introduces the short pattern waveform database or machine learning based measurement. Instead of extracting a single linear fit pulse response from a waveform, a new method is introduced above that can extract multiple linear fit pulse responses from a waveform. The multiple pulses contain more information of the signal. The discussion now turns to embodiments that use multiple pulses for machine learning based measurement. Machine learning techniques can significantly improve the speed of complex measurements. The measurement speed improvement translates to the improvement of production throughput.

When the signal speed increases, the equalizers in transmitter and receiver are widely used to improve the system performance. For example, PCIE Gen6 receiver has a 16-tap DFE in addition to a CTLE (continuous time linear equalizer). When the receivers have equalizers, some of the measurements are performed on the equalized signals. For example, in PCIE Gen6, the eye height and eye width measurements are defined based on the eye diagram of the equalized waveform. In the other example, IEEE 802.3 standards for 100 G/400 G specify the transmitter and dispersion eye closure (TDECQ) measurement as key pass/fail criteria for 26 GBaud and 53 GBaud PAM4 optical signaling. The TDECQ measurement involves a 5-tap FFE.

For complex and time-consuming measurements, the machine learning technique could provide significant improvement in the measurement speed. The information contained in the data used by machine learning affects the machine learning results. The '598 application describes the data containing short pattern waveforms for machine learning. The advantage is that the data has the time sequence information. However, the selected short patterns only appear in a portion of the whole data pattern. Certain conditions require processing long waveform to get sufficient appearances of the selected short patterns. The linear fit pulse response approach is more efficient to get the needed data for machine learning, as discussed in the '583 application. Instead of extracting a single pulse from the waveform, the method described above expands the single pulse extraction to multiple pulse extraction. The multiple pulses contain more information of the signal. For example, for a PAM4 signal, 4 pulses can better represent the 4 symbols. When the neural network sees more information, the more accurate measurement results can be obtained from machine learning.

To get more accurate measurement results, in particular for measurements that require equalizers, the input data to the neural network should contain time sequence information, since the equalizers operate on the time sequenced samples. The regular eye diagram data lost the time sequence information between symbols. The full pattern waveform could have a large size, making it slow to train the neural network. The short pattern waveform data set only uses a portion of the waveform, so it ignores the unused portion of the waveform which still contains signal information.

The single linear fit pulse response extraction technique has been used for measurements and equalizer adaptations. The linear fit pulse contains the time sequence information that is common for all data. The time sequence information is useful to analyze the inter-symbol-interference. The time sequence information can be used to determine equalization parameters such as FFE (feed forward equalizer) taps, DFE taps, and CTLE.

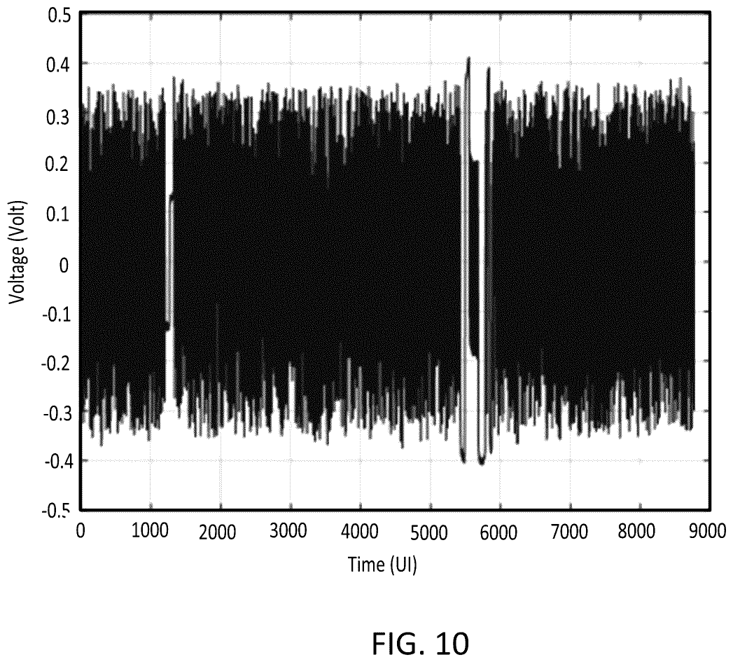

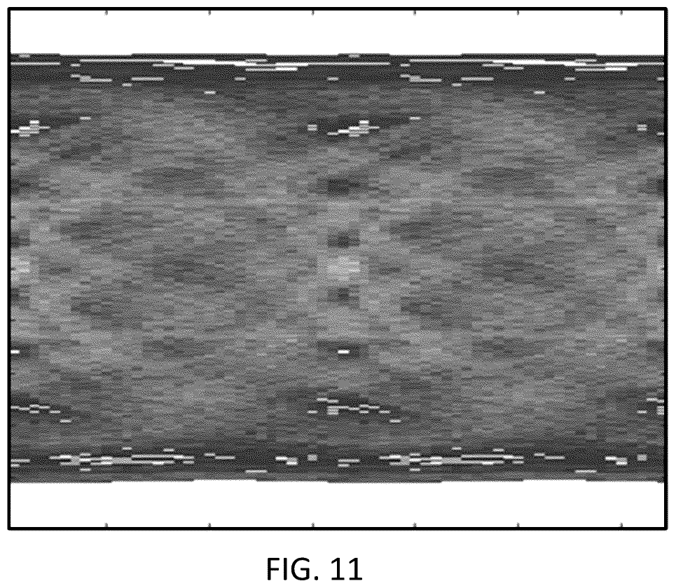

Multiple extracted pulses can better represent the signal, as discussed above. For example, FIG. 10 shows a waveform for a PAM4 signal, and FIG. 11 shows an eye diagram for that signal, with the eye completely closed due to the large channel loss.

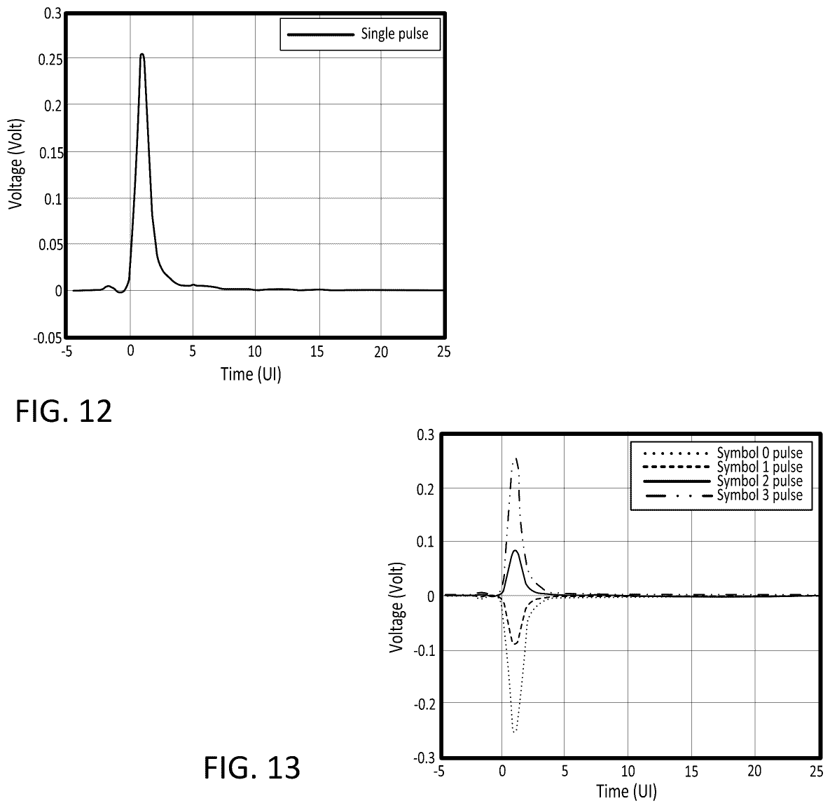

FIG. 12 shows a single linear fit pulse response extracted from the waveform. Even though the eye diagram is closed due to the channel loss, the linear fit pulse response extraction process successfully extracts out the pulse.

FIG. 13 shows the four symbols, [0 1 2 3] of the PAM4 signal extracted from the waveform using the multiple pulse extraction algorithm described above. In this example, the multiple pulse extraction algorithm also successfully extracts the pulses when the eye diagram is fully closed.

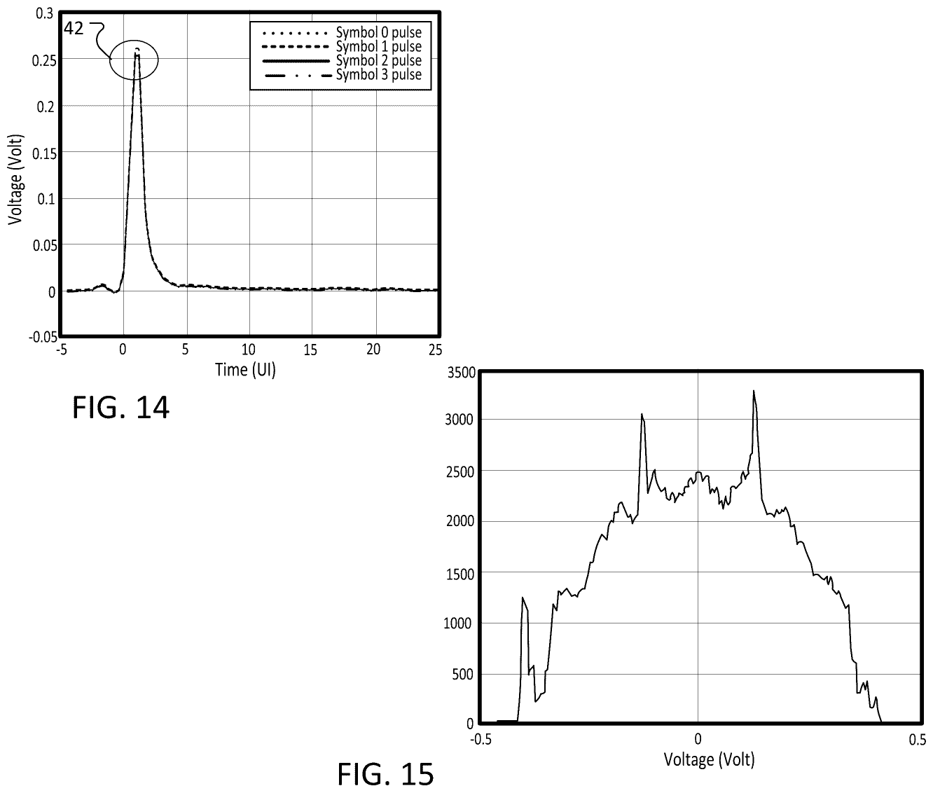

The four pulses can be normalized by multiplying the four pulses by [−1, −⅓, ⅓, 1] to get the normalized pulses as shown in FIG. 14. The overlay plot of the four normalized pulses reveals that the 4 symbols have differences in addition to the nominal scaling factor of [−1 −⅓ ⅓ 1]. In FIG. 14, the differences are most noticeable at the peak of the pulses shown by circle 42. These differences comprise the additional characterization information about the signal compared to the single pulse representation.

Depending on the measurement requirements, the other data can also be used with multiple pulses for machine learning. For example, the vertical histogram of the whole waveform or the vertical histogram at the eye center can be used. The vertical histogram of the whole waveform is shown in FIG. 15.

For different choice of machine learning methods, the multiple pulses and the vertical histogram can be arranged in proper formats. For example, each of the multiple pulses and the vertical histogram are all 1-dimensional vectors, so they can be treated as the 1-D data set and fed into neural networks that handle 1-D data. Examples include RNN (recurrent neural networks), the LSTM (long short-term memory), and the 1-D CNN (convolutional neural network). The data set can also be organized as tabular data. Another embodiment puts the data into a 2-D image and uses the 2-D CNN models.

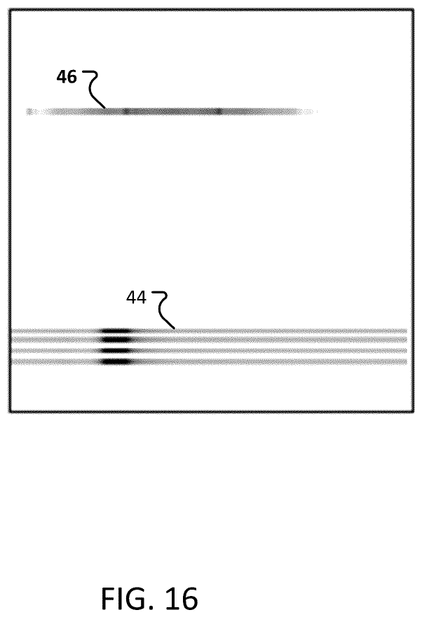

FIG. 16 shows the multiple pulses extracted from the waveform as shown of FIG. 13 represented by the grey lines at the bottom such as 44, where darker color is associated with higher amplitude in the linear fit pulses. The vertical histogram shown in FIG. 15 is represented by the grey line 46 on the top, where darker color is associated with more hits.

If the pulse responses have longer duration, each of the pulses can be represented by multiple lines in the 2-D image.

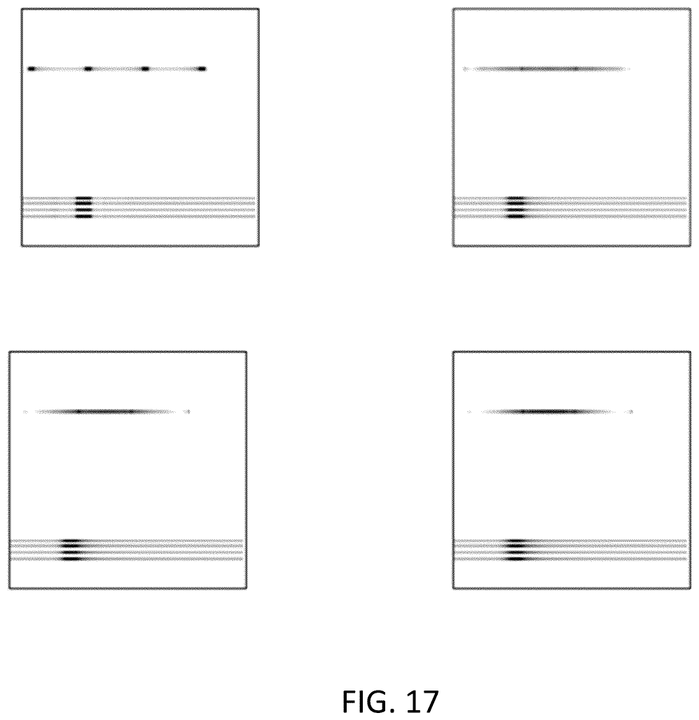

Training the CNN requires a large training data set. In one embodiment, the data set is obtained from a lab test using the BERT, the board with a variety of channels, and the real-time oscilloscopes. The images shown in FIG. 17 represent 4 acquired signals with different linear fit pulses and different vertical histograms. These images cover the same characteristics as the images in FIG. 16.

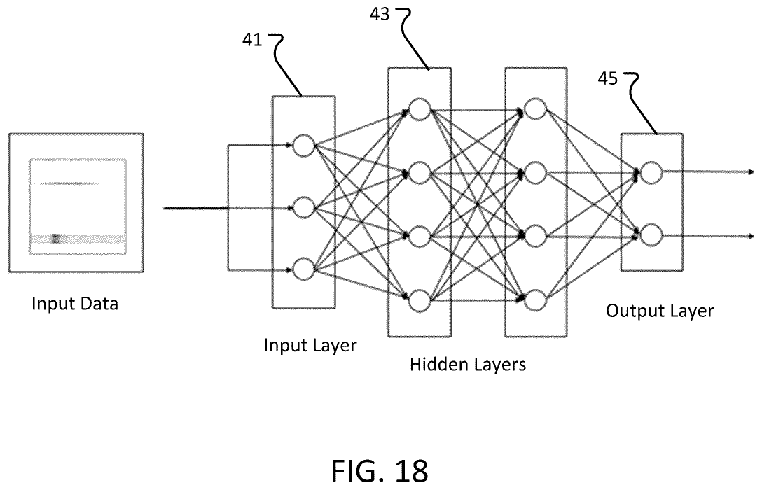

FIG. 18 shows an embodiment of a CNN model using multiple pulses as input to the input layer 41. The CNN could have multiple hidden layers such as 43 and produces the tuning parameters or test results at output layer 45. Many existing deep learning CNN models can be used for measurements, for transmitter tuning, and for receiver equalizer adaptation.

An embodiment of a process of using the multiple extracted pulses for machine learning measurements starts by acquiring the waveform on real time (RT) or equivalent time (ET) oscilloscopes or other test and measurement instrument. The instrument then runs software clock recovery or hardware clock recovery to get the pattern waveform. Using the multiple pulse extraction fitting process discussed above to extract multiple pulses from the waveform. To improve the speed, the fitting process may only use a portion of the waveform, for example, on a portion that covers about 10,000 symbols. Because the fitting process uses every symbol, 10,000 symbols provide sufficient data to get the accurate linear fit pulses. Portions that cover other quantities of symbols may also be used.

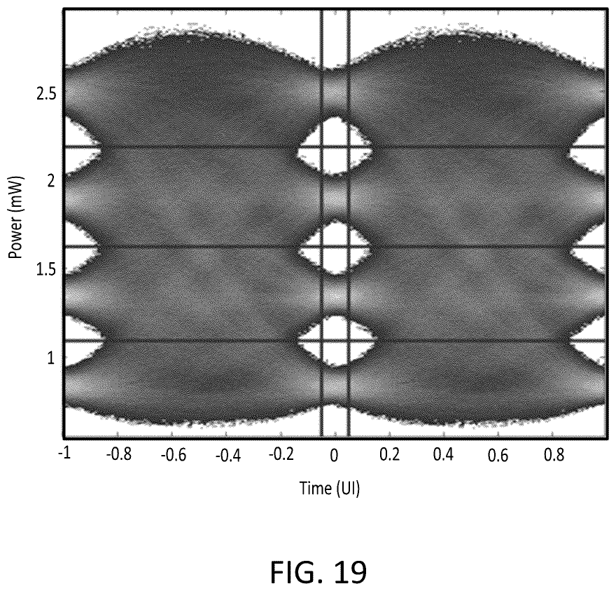

The process may choose other data types that provide related information for the measurement. For example, the vertical histogram at the center of the UI is selected for the signal to noise ratio (SNR) measurement. Two vertical histograms around the center of the UI are selected for TDECQ measurement. Jitter measurement uses the horizontal histogram at the edge crossing level(s). Multiple vertical histograms, multiple horizontal histograms, combination of vertical histograms and horizontal histograms can also be considered and used in various embodiments. FIG. 19 is an example with an optical signal with the locations of the various histograms identified by the lines.

Once the data types have been selected, the process must choose the data representations that fit the neural network for machine learning. For example, the extracted linear fit pulses and the vertical histogram are represented in the 2-D image shown in FIG. 16. The extracted linear fit pulses and 1-D histogram can also be represented in 1-D data set. The neural network could have various structures. When a pre-trained deep learning network model is used, transfer learning could be performed. In transfer learning, only the last fully connected layer is trained with the data set having the linear fit pulses. The data set fed into the neural network is normalized. The results are then de-normalized. For example, the label values are normalized for neural network training. After the neural network training is complete, and it has performed its prediction, the prediction result is de-normalized which is the inverse map of normalization.

Other modifications and variations exist. Beside the linear fit pulse responses, other linear responses such as impulse responses and step responses can also be extracted from an acquired pattern waveform and used as input to a machine learning model.

The linear fit pulses data set can be combined with selected short pattern waveforms data set, as described in the '598 application, for machine learning.

The PAM4 signal is used to describe the multiple pulses for machine learning. As stated above, the multiple pulse algorithm can be applied to other PAMn signals, for example, n=3 for PAM3, n=6 for PAM6.

Other parameters can also be incorporated into the 2D-image, for example, the scope noise value can be represented by a line or bar in the image.

The above embodiments describe a new input data selection for machine learning to improve the speed and the accuracy of measurements from machine learning by using multiple extracted linear pulses. This approach puts the essential information of the signal in a compact form that can be fed into the neural network for machine learning.

When the signal speed increases, the equalizers in transmitter and receiver are widely used to improve the system performance. For example, as shown in table 2, for generations of PCIE, the number of DFE (decision feedback equalizer) taps increases from 1 in Gen3 to 16 in Gen6 as the transmission speed increases from 8 GT/s to 64 GT/s, and the signal modulation scheme changes from NRZ in generations before Gen6 to PAM4 in Gen6.

TABLE 2
PCIE DFE

| | Transmission | Number of | Signal |
|---|---|---|---|
| | speed | DFE taps | modulation |
| Gen3 | 8GT/s | 1 | NRZ |
| Gen4 | 16GT/s | 2 | NRZ |
| Gen5 | 32GT/s | 3 | NRZ |
| Gen6 | 64GT/s (32GBaud) | 16 | PAM4 |

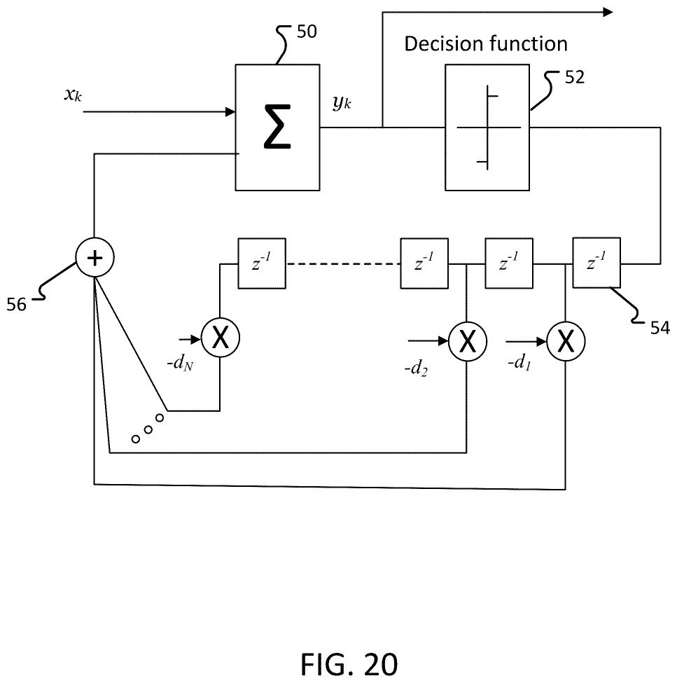

The traditional DFE structure is shown in FIG. 20. In FIG. 20, xₖ is the input to the DFE at 50, and yₖ is the input to the decision function, also called the slicer, 52. The decision function detects the symbol in digital sense. For the NRZ signals, its output could be −1, 1 representing bit 0 and bit 1, and for the PAM4 signals, its output could be −1, −⅓, ⅓, 1 representing symbol 0, symbol 1, symbol 2, symbol 3. The decision function output is then fed into the delay blocks such as 54 along the delay line, the delay block outputs are multiplied with DFE taps d₁ and then feedback to the sum node to get summed with the input signal xₖ. N is the number of DFE taps. For PCIE Gen3, N=1. For PCIE Gen6, N=16.

U.S. Pat. No. 11,765,002, “EXPLICIT SOLUTION FOR DFE OPTIMIZATION WITH CONSTRAINTS,” issued Sep. 19, 2023, discloses an explicit solution that finds the best DFE taps based on the single LFPR, and is incorporated by reference herein in its entirety.

In a PAM4 signal, the normalized pulses for symbol 0, 1, 2, 3 are often different, as discussed above. The multiple LFPR method described above, which is hereby incorporated by reference into this disclosure, can be used to extract the multiple LFPR for the multiple symbols. The multiple LFPR captures more details of the signal than the single LFPR does, providing the opportunity to improve the DFE design that could improve the equalizer performance.

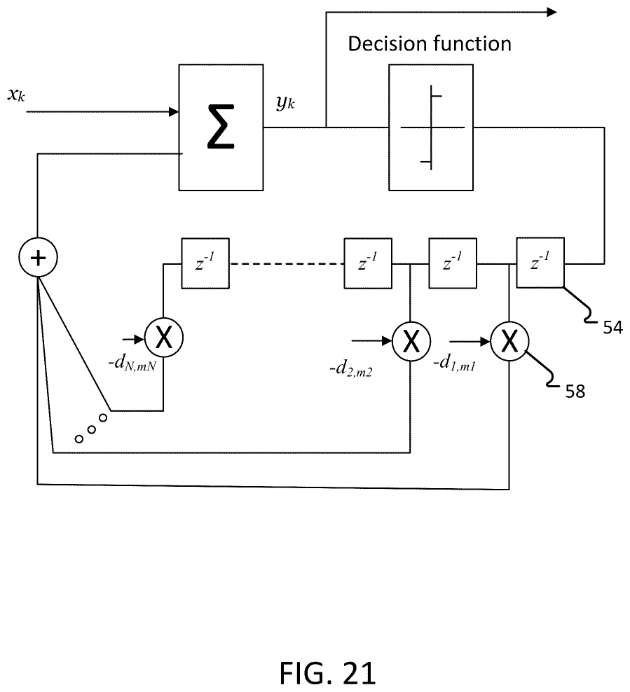

The traditional DFE structure shown in FIG. 20 has a single set of tap values. A new DFE structure called MPDFE (Multiple Pulse DFE) is described in FIG. 21, where each of the DFE taps d_{i,mi} is chosen from a pre-determined set of tap values based on the detected symbol going through the delay blocks. The index i is the tap number and the index mi is the symbol “number” based upon the signal.

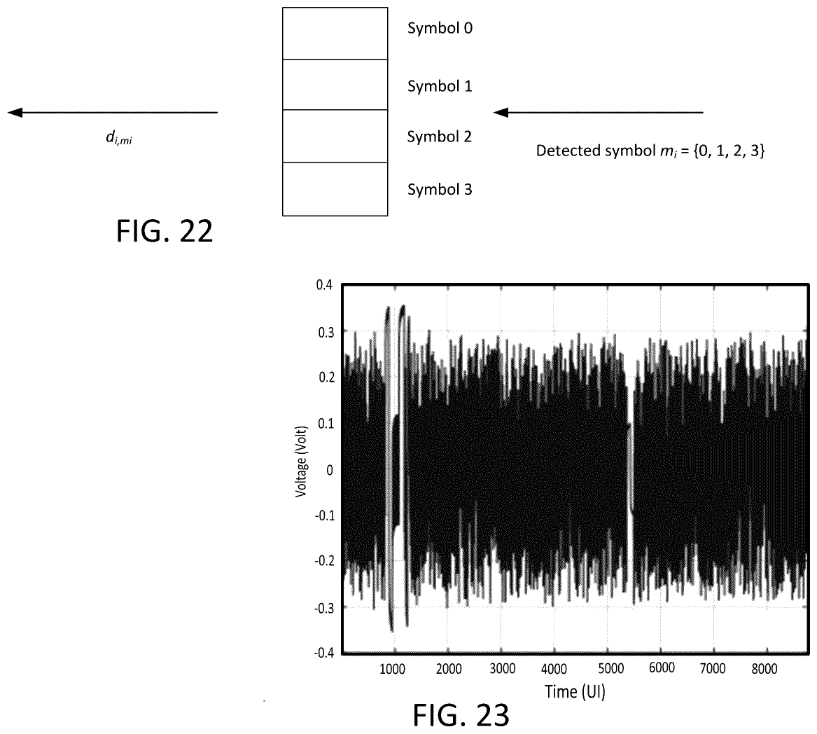

For example, as shown in FIG. 21, there are 4 possible tap values for a PAM4 signal at each delay line position. The d_{i,mi} has two indexes, as mentioned above, the first index represents the delay line position that corresponds to the tap, and the second index represents the symbol. FIG. 22 shows an example. If, for example the delay position 1, 54 in FIG. 21, i=1, m1={0,1,2,3}. If the symbol is 2, then m1=2 and the tap value d_{1,2} is selected for the delay line position 1. If next symbol is 0, then m1=0, and the tap value d_{1,0} is selected for the delay line position 1. The tap values are selected in the same way for all delay line positions. In next clock cycle, the detected symbols shift through the delay blocks along the delay line, the tap value selections are updated based on the updated symbols at the corresponding delay line positions. In one embodiment, filters may use multipliers, such as (−1, −⅓, ⅓ and 1) for PAM4 symbols 0, 1, 2 and 3, that are multiplied with the tap values (d_{1,1} d1,_{1,2} . . . d_{i,mi}), for example at multiplier 58 in FIG. 21. The product of the tap value and the multiplier could be stored in a lookup table and the filter would access the value from the table based upon the symbol.

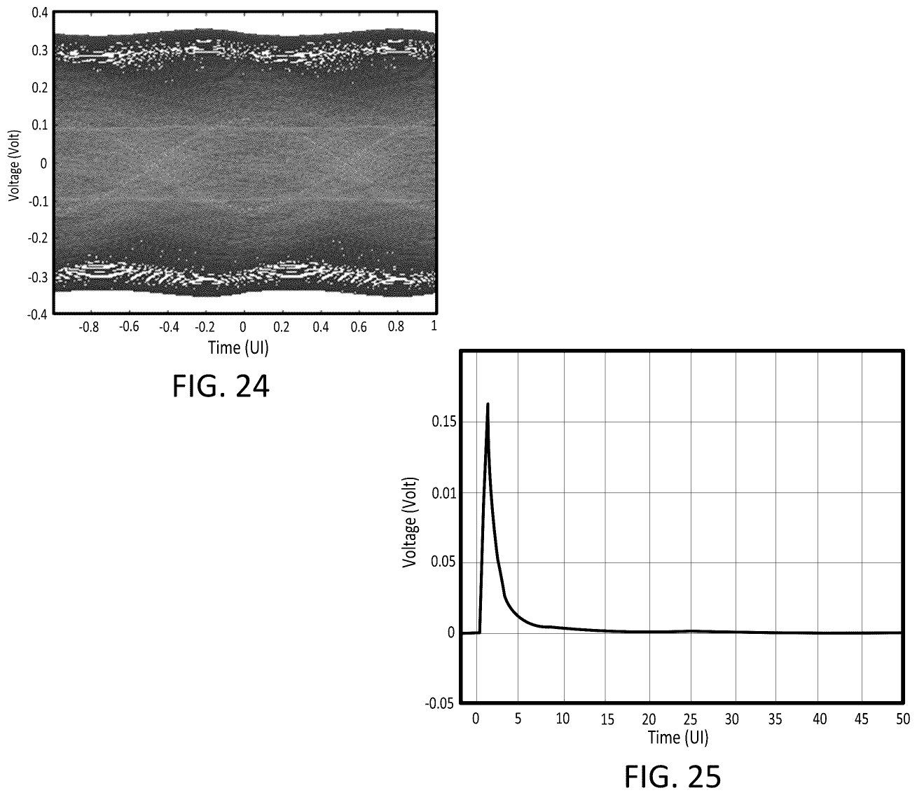

The process to determine the tap values for MPDFE is described with a numerical example. A PAM4 signal with the pattern waveform shown in FIG. 23 has a closed eye diagram shown in FIG. 24. The single LFPR extracted from the pattern waveform is shown in FIG. 25.

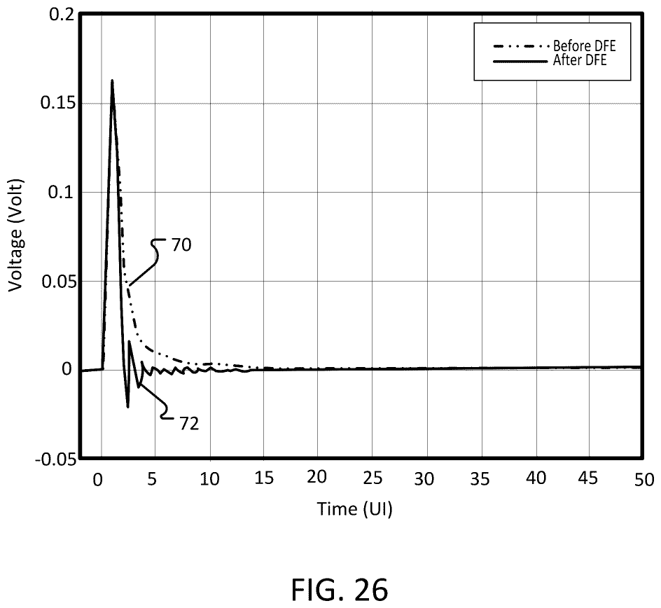

The taps of the traditional DFE are determined to minimize the amplitudes of the post cursor samples at the centers of unit intervals (UI). As shown in FIG. 26, curve 70 shows the LFPR before applying the DFE, and curve 72 shows the LFPR after the DFE being applied. As shown, the DFE minimizes the amplitudes of the samples at UI centers to zero for the post cursors. This example used a 40-tap DFE.

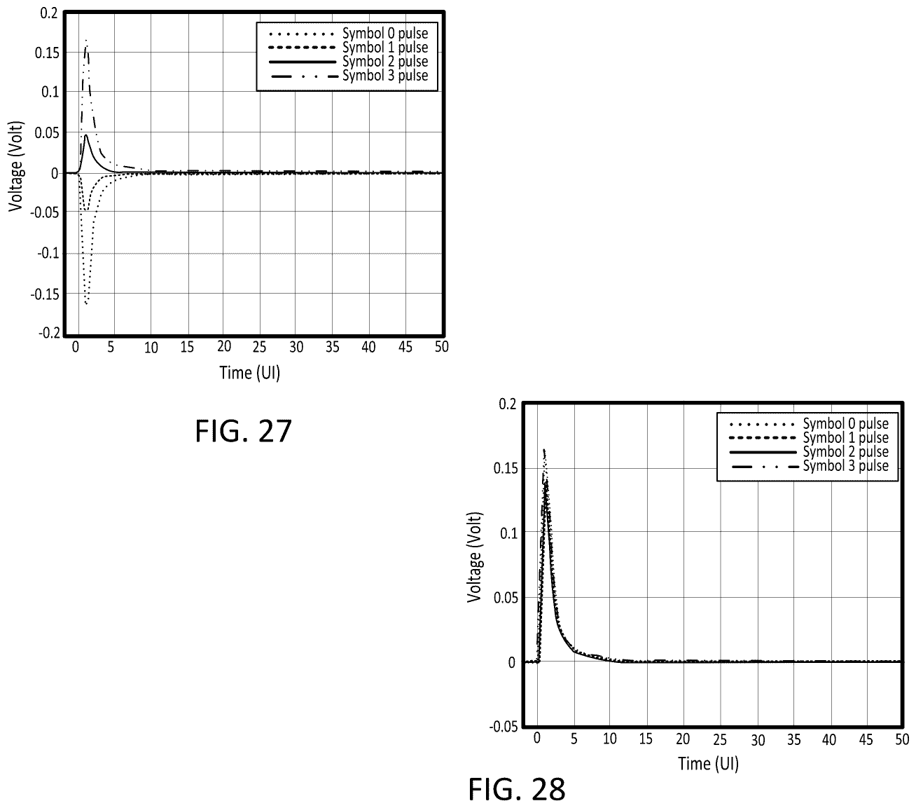

However, for a PAM4 signal, the normalized pulses for all symbols are not always the same. The multiple pulses for the multiple symbols can be extracted according to the method set out above. The un-normalized pulses are shown in FIG. 27, and the normalized pulses are shown in FIG. 28. The un-normalized pulses represent the actual size of the pulses for the symbols, the normalized pulses are scaled based on the symbol 0, 1, 2, 3 being represented by the values of −1, −⅓, ⅓, 1 in the pattern.

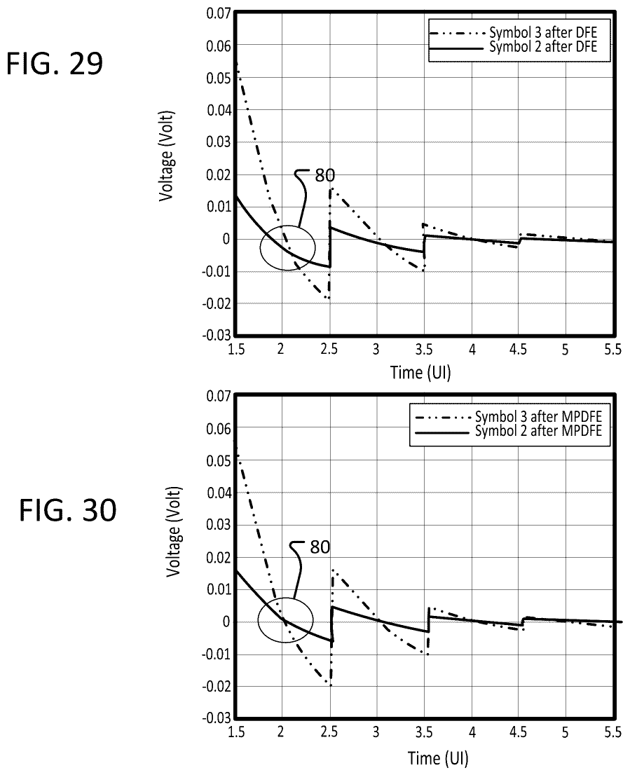

Note that some of the normalized pulses are very similar to each other, but not all of the normalized symbol pulses are the same as shown in FIG. 28, most noticeable at the top of the pulse. When applying the single set of DFE taps based on the single LFPR to each of the normalized multiple pulses, the DFE cannot minimize the samples at the UI center to zero for all of the multiple pulses when the pulses are not all the same at the UI centers. In this numerical example, applying the DFE taps determined from the single LFPR to the un-normalized symbol pulses yields the non-zero residuals at the UI centers in the after-DFE pulses for symbol 3 and symbol 2, as shown in FIG. 29. Looking at circle 80, one can see that at 2, the center of the UI interval between 1.5 and 2.5, the residuals are not zero.

With multiple LFPR extraction, the MPDFE determines the tap values d_{j,k} for j=0,1,2,3 representing the 4 symbols and k=1,2, . . . , L where L represents the MPDFE length. For each symbol j, the tap values d_{j,k} are optimized to minimize the post cursor residuals at the UI centers. The explicit solution described above can be applied for each pulse. In this numerical example, applying the MPDFE taps to the symbol pulses yields zero residuals at the UI centers of the after DFE pulses for the un-normalized symbol 3 and symbol 2, shown in FIG. 30. One can see that the pulses are zero at the UI center highlighted by circle 80, unlike that of. FIG. 29.

Once the DFE taps are determined for every symbol, the MPDFE can be implemented as shown in FIGS. 21 and 22. As an example to aid in understanding, a 40-tap DFE filter has 40 tap values. In the MPDFE approach for PAM4 as an example, each of the 40 taps now have four values each, for a total of 160 values. As the symbol comes in, for example, to delay position 1, the MPDFE approach results in the tap value for that symbol at that tap.

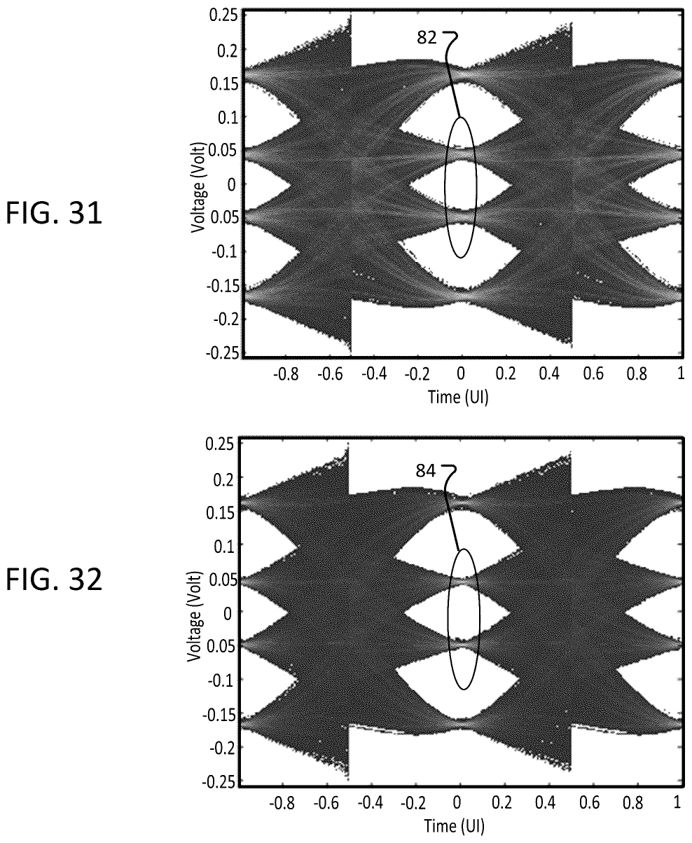

As a comparison, FIG. 31 shows the eye diagram after application of the traditional DFE. FIG. 32 shows the eye diagram after application of the MPDFE. The difference is subtle, because both approaches apply a DFE to open the eye, but if one looks in the region 82 in FIG. 31, and compares it to region 84 in FIG. 32, one can see that the areas between the open eyes in FIG. 31 are larger because the eyes are less open. The eye diagram after MPDFE shown in FIG. 32 having wider eye openings than the eye diagram after the traditional DFE shown in FIG. 31, demonstrates the improvement provided by MPDFE over the traditional DFE.

The Maximum-likelihood sequence estimation equalizers (MLSE) provide optimal equalization if the channel characteristics are known or accurately estimated. However, MLSE equalizers have higher computational complexity than the traditional DFE. If the channel characteristics are known or accurately estimated, the MLSE equalizers can fully cover the range of the channel response. The computation complexity of MLSE is M^{L} where M is the number of symbols and L is the length of the equalizer. Because of the exponential function, the L cannot be too large to make the MLSE feasible to implement. For example, the Matlab has an upper limit of 2²⁰ on the complexity for MLSE. Since 2²⁰ equals 4¹⁰, it means the MLSE in Matlab cannot completely cover a channel response last longer than 10 UI. In this numerical example, the channel response lasts over 20 UI as indicated by FIG. 26 and FIG. 28. Note that when the high-speed signal doubles its symbol rate, the number of UI within a fixed time period also doubles. The higher computational complexity of MLSE increases the cost to implement and so limits its applications.

The comparison of the computational complexity of the traditional DFE, MPDFE and MLSE is summarized in Table 3.

TABLE 3
Computational complexity formula

| Equalizer type | Computational complexity |
|---|---|
| DFE | M × L |
| MPDFE | M × L |
| MLSE | M^{L} |

The numerical values of the computational complexity for the three configurations of the equalizers for M=4, L=10, 20, 40 are shown in Table 4.

TABLE 4
Computational complexity in numbers for M = 4

| Equalizer type | L = 10 | L = 20 | L = 40 |
|---|---|---|---|
| DFE | 40 | 80 | 160 |
| MPDFE | 40 | 80 | 160 |
| MLSE | 1.04E6 | 1.10E12 | 1.21E24 |

The MPDFE concept can also be applied to even and odd pulses as discussed above, and to any other multiple pulses cases for various modulation schemes, for example, PAM8 signaling.

The embodiments here provide MPDFE, a new DFE structure that improves the equalization performance without increasing the same computational complexity and implementation cost. The advancement in semiconductors enables the new generations of receivers with higher computation power with lower power consumption and reduced cost. The increase of signal speed, for example, 400 G to 800 G, and more complex modulation scheme, for example, NRZ to PAM4 to PAM8, impose more challenges for the receivers to successfully compensate the signal impairments. MPDFE is an attractive technique to improve the receiver performance without increase of cost.

One embodiment comprises a computing device, comprising: a port to allow the computing device to receive a signal from a device under test (DUT); one or more processors configured to execute code that causes the one or more processors to: acquire a waveform from the signal; derive a pattern waveform from the waveform using one of either hardware or software clock recovery, the pattern comprising a number of symbols based upon a type of the signal; perform linear fit pulse response (LFPR) extractions on the pattern waveform to extract more than one pulse response; extract a pulse response for each symbol; define a multiple pulse decision feedback equalizer (MPDFE) having a number of taps; use the pulse response for each symbol to determine a set of MPDFE tap coefficients for that symbol; and apply the coefficient for a given symbol at each delay position in the MPDFE as the symbol shifts through the delay line of the MPDFE structure.

Another embodiment comprises the computing device above, wherein the code that causes the one or more processors to extract the pulse response for each symbol comprises code that causes the one or more processors to extract one of linear fit pulse responses (LFPR), impulse responses, or step responses.

Another embodiment comprises the computing device above, wherein the code that causes the one or more processors to use the pulse response for each symbol to determine a set of DFE taps for that symbol comprises code that causes the one or more processors to select a set of DFE tap values that minimizes amplitudes of post cursor samples at the center of unit intervals for each symbol.

Another embodiment comprises the computing device above, wherein the code further comprises code that causes the processors to use normalized pulses for each symbol to determine the DFE tap values.

Another embodiment comprises the computing device above, wherein the port connects to a high-speed communications link.

Another embodiment comprises the computing device above, wherein the computing device comprises a test and measurement instrument.

Another embodiment comprises the computing device above, wherein the type of signal is one of a PAM4 or a PAM8 signals.

Another embodiment comprises the computing device above, wherein the number of taps is 16.

Another embodiment comprises the computing device above, wherein the code that causes the one or more processors to apply the coefficient for a given symbol at each delay position in MPDFE structure as the symbol shifts through the delay line of the MPDFE structure comprises code to multiply the symbol by the coefficient and a symbol multiplier based upon the symbol.

Another embodiment comprises the computing device above, wherein code that causes the one or more processors to multiply the symbol by the coefficient and a symbol multiplier based upon the symbol comprises code that causes the one or more processors to access a look up table that stores a product of the multiplier for each symbol at each delay position to obtain the product based upon the symbol.

Another embodiment comprises the computing device above, wherein the processors are further configured to execute code that causes the one or more processors to average multiple repetitions of the pattern waveform to produce an averaged pattern waveform as the pattern waveform.

Another embodiment comprises a method of optimizing an equalizer for a communication link, comprising: receiving a signal from a device under test (DUT) acquiring a waveform from the signal; deriving a pattern waveform from the waveform using one of either hardware or software clock recovery, the pattern comprising a number of symbols based upon a type of the signal; performing linear fit pulse response (LFPR) extractions on the pattern waveform to extract more than one LFPR; extracting a pulse response for each symbol; defining a multiple pulse decision feedback equalizer (MPDFE) having a number of taps; determining a set of tap values for each symbol using the pulse response for each symbol; and applying the coefficient for a given symbol at each delay position in the MPDFE as the symbol shifts through the delay line of the MPDFE structure.

Another embodiment comprises the method above, wherein extracting the pulse response for each symbol comprises extracting one of linear fit pulse responses (LFPR), impulse responses, or step responses.

Another embodiment comprises the method above, wherein determining a set of taps for each symbol comprises selecting a tap value that minimizes amplitudes of post cursor samples at the center of unit intervals for each symbol.

Another embodiment comprises the method above, further comprising using the normalized pulses for each symbol to determine the tap.

Another embodiment comprises the method above, wherein the type of signal is one of a PAM4 signal or a PAM8 signal.

Another embodiment comprises the method above, wherein the type of signal is a Peripheral Component Interconnect Express (PCIE) signal that conforms to PCIE Gen6

Another embodiment comprises the method above, wherein the number of taps is 16.

Another embodiment comprises the method above, wherein applying the coefficient for a given symbol at each delay position in MPDFE structure as the symbol shifts through the delay line of the MPDFE structure comprises multiplying the symbol by the coefficient and a symbol multiplier based upon the symbol.

Another embodiment comprises the method above wherein multiplying the symbol by the coefficient and a symbol multiplier comprises accessing a look up table that stores a product of the multiplier for each symbol at each delay position to obtain the product based upon the symbol.

Another embodiment comprises the method above, further comprising averaging multiple repetitions of the pattern waveform to produce an averaged pattern waveform as the pattern waveform.

Aspects of the disclosure may operate on particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### Examples

Illustrative examples of the disclosed technologies are provided below. An embodiment of the technologies may include one or more, and any combination of, the examples described below.

Example 1 is a test and measurement instrument, comprising: a port to allow the instrument to receive a signal from a device under test (DUT); one or more processors configured to execute code that causes the one or more processors to: acquire a waveform from the signal; derive a pattern waveform from the waveform using one of either hardware or software clock recovery; perform linear fit pulse response (LFPR) extractions on the pattern waveform to extract more than one LFPR; determine a reference pulse response from the more than one LFPRs; compare at least one of the LFPRs to the reference pulse response to determine a difference; and tune the DUT to reduce the difference.

Example 2 is the test and measurement instrument of Example 1, wherein the code that causes the one or more processors to perform LFPR extractions to extract more than one LFPR comprises code that causes the one or more processors to perform one of extracting LFPRs on pulses from even and odd unit intervals, extracting LFPRs on symbol pulses, or extracting LFPRs on symbol pulses from even and odd unit intervals.

Example 3 is the test and measurement instrument of Example 2, wherein the symbol pulses result from PAM4 symbols.

Example 4 is the test and measurement instrument of Example 2, wherein the symbol pulses result from a signal having n symbol pulses.

Example 5 is the test and measurement instrument of any of Examples 1 through 4, wherein the code that causes the one or more processors to determine the reference pulse response comprises code that causes the one or more processors to determine an average pattern waveform.

Example 6 is the test and measurement instrument of Example 5, wherein the code that causes the one or more processors to determine the reference pulse response comprises code that causes the one or more processors to: normalize the more than one LFPRs; calculate an average pulse; and use the average pulse as the reference pulse.

Example 7 is the test and measurement instrument of any of Examples 1 through 6, wherein the code that causes the one or more processors to determine the reference pulse response comprises code to cause the one or more processors to compare two or more LFPRs, wherein one of the two or more LFPRs acts as the reference pulse.

Example 8 is the test and measurement instrument of any of Examples 1 through 7, wherein the one or more processors are further configured to cause the one or more processors to repeat the acquiring, deriving, performing, determining, comparing, and tuning until the difference has been minimized.

Example 9 is the test and measurement instrument of any of Examples 1 through 8, wherein the code that causes the one or more processors to perform LFPR to extract more than one LFPR comprises code that causes the one or more processors to: construct a symbol matrix, X_{N}_{ₚ}, and a waveform matrix, Y, based on the data pattern sequency and the pattern waveform; construct switch matrices based upon a type of multiple pulses to be used; use the switch matrices and X_{N}_{ₚ} to construct the extended symbol matrix; solve for a coefficient matrix from the extended symbol matrix; and obtain the more than one LFPR by reading pulse samples for each pulse from the coefficient matrix.

Example 10 is the test and measurement instrument of Example 9, wherein the one or more processors are further configured to execute code that causes the one more processors to: construct an error matrix, E, taking a matrix multiplication of the coefficient matrix and the extended symbol matrix and subtracting the waveform matrix, Y.

Example 11 is the test and measurement instrument of any of Examples 1 through 10, wherein the one or more processors are further configured to execute code that causes the one or more processors to average multiple repetitions of the pattern waveform to produce an averaged pattern waveform as the pattern waveform.

Example 12 is a method of calibrating a transmitter, comprising: acquiring a waveform from a signal received from the transmitter; deriving a pattern waveform from the waveform using one of either hardware or software clock recovery; performing linear fit pulse response (LFPR) extractions on the pattern waveform to extract more than one LFPR; determining a reference pulse response from the more than one LFPRs; comparing at least one of the LFPRs to the reference pulse response to determine a difference; and tuning the transmitter to reduce the difference.

Example 13 is the method of Example 12, wherein performing LFPR extractions to extract more than one LFPR comprises one of extracting pulses from even and odd unit intervals, extracting symbol pulses, or extracting symbol pulses from even and odd unit intervals.

Example 14 is the method of either of Examples 12 or 13, wherein determining the reference pulse response comprises determining an average pulse, and determining the reference pulse comprises: normalizing the more than one LFPRs; calculating an average pulse; and using the average pulse as the reference pulse.

Example 15 is the method of any of Examples 12 through 14, wherein determining the reference pulse response comprises comparing two or more LFPRs, wherein one of the two or more LFPRs acts as the reference pulse.

Example 16 is the method of any of Examples 12 through 15, further comprising repeating the acquiring, deriving, performing, determining, comparing, and tuning until the difference has been minimized.

Example 17 is the method of any of Examples 12 through 16, further comprising averaging multiple repetitions of the pattern waveform to produce an averaged pattern waveform as the pattern waveform.

Example 18 is a test and measurement instrument, comprising: one or more ports configured to receive a signal from one or more devices under test (DUT); and one or more processors configured to execute code that causes the one or more processors to: acquire a waveform from the signal; derive a pattern waveform from the waveform using one of either hardware or software clock recovery; extract more than one pulse response from the pattern waveform by performing linear fit pulse response (LFPR) extractions on the pattern waveform; present one or more data representations including a data representation of the more than one pulse responses to a machine learning network to produce a measurement prediction for the DUT; and receive the measurement prediction for the DUT from the machine learning network.

Example 19 is the test and measurement instrument of Example 18, wherein the one or more data representations comprise one or more of a vertical histogram of the whole pattern waveform, a vertical histogram at the center of a unit interval of an eye diagram representation of the pattern waveform, two vertical histograms around a center of the unit interval of the eye diagram, and a horizontal histogram at an edge of crossing levels of the eye diagram.

Example 20 is the test and measurement instrument of either of Examples 18 or 19, wherein the machine learning network employs a neural network that handles one-dimensional data and the code that causes the one or more processors to present the one or more data representations comprises code that causes the one or more processors to present a one-dimensional data set comprising a vertical histogram at an eye center of an eye diagram representation of the waveform.

Example 21 is the test and measurement instrument of any of Examples 18 through 20, wherein the machine learning network employs a neural network that handles two-dimensional data and the code that causes the one or more processors to present the one or more data representations comprises code that causes the one or more processors to present a two-dimensional data set comprising the extracted more than one pulse responses and at least one histogram.

Example 22 is the test and measurement instrument of Example 21, wherein the two-dimensional data includes pixels having a darkness that corresponds to one of an amplitude of the extracted pulse response and a number of hits in a histogram.

Example 23 is the test and measurement instrument of any of Examples 18 through 22, wherein the code that causes the one or more processors to present the one or more data representations to the machine learning network causes the one or more processors to normalize the one or more data representations prior to presenting the one or more data representations to the machine learning network, and to de-normalize the prediction of the measurement received from the machine learning network.

Example 24 is the test and measurement instrument of any of Examples 18 through 23, wherein the code that causes the one or more processors to present the one or more data representations of the more than one pulse responses to the machine learning network comprises code that causes the one or more processors to present the data representation to the machine learning network for a measurement comprising one or more of signal to noise distortion ratio (SNDR), signal to noise ratio (SNR), jitter, and transmitter dispersion eye closure quaternary (TDECQ).

Example 25 is the test and measurement instrument of any of Examples 18 through 24, wherein the one or more processors are further configured to execute code that causes the one or more processors to train the machine learning network for a selected measurement.

Example 26 is the test and measurement instrument of any of Examples 18 through 25, wherein the code that causes the one or more processors to extract the more than one pulse response comprises code that causes the one or more processors to extract of one of a linear fit pulse response (LFPR), impulse response, and step response.

Example 27 is the test and measurement instrument of any of Examples 18 through 27, wherein the one or more processors are further configured to execute code that causes the one or more processors to average multiple repetitions of the pattern waveform to produce an averaged pattern waveform as the pattern waveform.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although specific aspects of this disclosure have been illustrated and described for purposes of illustration, it will be understood that various modifications may be made without departing from the spirit and scope of the invention. Accordingly, the invention should not be limited except as by the appended claims.

1. A test and measurement instrument, comprising:
a port to allow the instrument to receive a signal from a device under test (DUT);
one or more processors configured to execute code that causes the one or more processors to:
acquire a waveform from the signal;
derive a pattern waveform from the waveform using one of either hardware or software clock recovery;
perform linear fit pulse response (LFPR) extractions on the pattern waveform to extract more than one LFPR;
determine a reference pulse response from the more than one LFPRs;
compare at least one of the LFPRs to the reference pulse response to determine a difference; and
tune the DUT to reduce the difference.

2. The test and measurement instrument as claimed in claim 1, wherein the code that causes the one or more processors to perform LFPR extractions to extract more than one LFPR comprises code that causes the one or more processors to perform one of extracting LFPRs on pulses from even and odd unit intervals, extracting LFPRs on symbol pulses, or extracting LFPRs on symbol pulses from even and odd unit intervals.

3. The test and measurement instrument as claimed in claim 2, wherein the symbol pulses result from PAM4 symbols.

4. The test and measurement instrument as claimed in claim 2, wherein the symbol pulses result from a signal having n symbol pulses.

5. The test and measurement instrument as claimed in claim 1, wherein the code that causes the one or more processors to determine the reference pulse response comprises code that causes the one or more processors to determine an average pattern waveform.

6. The test and measurement instrument as claimed in claim 5, wherein the code that causes the one or more processors to determine the reference pulse response comprises code that causes the one or more processors to:
normalize the more than one LFPRs;
calculate an average pulse; and
use the average pulse as the reference pulse.

7. The test and measurement instrument as claimed in claim 1, wherein the code that causes the one or more processors to determine the reference pulse response comprises code to cause the one or more processors to compare two or more LFPRs, wherein one of the two or more LFPRs acts as the reference pulse.

8. The test and measurement instrument as claimed in claim 1, wherein the one or more processors are further configured to cause the one or more processors to repeat the acquiring, deriving, performing, determining, comparing, and tuning until the difference has been minimized.

9. The test and measurement instrument as claimed in claim 1, wherein the code that causes the one or more processors to perform LFPR to extract more than one LFPR comprises code that causes the one or more processors to:
construct a symbol matrix, X_{N}_{ₚ}, and a waveform matrix, Y, based on the data pattern sequency and the pattern waveform;
construct switch matrices based upon a type of multiple pulses to be used;
use the switch matrices and X_{N}_{ₚ} to construct the extended symbol matrix;
solve for a coefficient matrix from the extended symbol matrix; and
obtain the more than one LFPR by reading pulse samples for each pulse from the coefficient matrix.

10. The test and measurement instrument as claimed in claim 9, wherein the one or more processors are further configured to execute code that causes the one more processors to:
construct an error matrix, E, taking a matrix multiplication of the coefficient matrix and the extended symbol matrix and subtracting the waveform matrix, Y.

11. The test and measurement instrument as claimed in claim 1, wherein the one or more processors are further configured to execute code that causes the one or more processors to average multiple repetitions of the pattern waveform to produce an averaged pattern waveform as the pattern waveform.

12. A method of calibrating a transmitter, comprising:
acquiring a waveform from a signal received from the transmitter;
deriving a pattern waveform from the waveform using one of either hardware or software clock recovery;
performing linear fit pulse response (LFPR) extractions on the pattern waveform to extract more than one LFPR;
determining a reference pulse response from the more than one LFPRs;
comparing at least one of the LFPRs to the reference pulse response to determine a difference; and
tuning the transmitter to reduce the difference.

13. The method as claimed in claim 12, wherein performing LFPR extractions to extract more than one LFPR comprises one of extracting pulses from even and odd unit intervals, extracting symbol pulses, or extracting symbol pulses from even and odd unit intervals.

14. The method as claimed in claim 12, wherein determining the reference pulse response comprises determining an average pulse, and determining the reference pulse comprises:
normalizing the more than one LFPRs;
calculating an average pulse; and
using the average pulse as the reference pulse.

15. The method as claimed in claim 12, wherein determining the reference pulse response comprises comparing two or more LFPRs, wherein one of the two or more LFPRs acts as the reference pulse.

16. The method as claimed in claim 12, further comprising repeating the acquiring, deriving, performing, determining, comparing, and tuning until the difference has been minimized.

17. The method as claimed in claim 11, further comprising averaging multiple repetitions of the pattern waveform to produce an averaged pattern waveform as the pattern waveform.

18. A test and measurement instrument, comprising:
one or more ports configured to receive a signal from one or more devices under test (DUT); and
one or more processors configured to execute code that causes the one or more processors to:
acquire a waveform from the signal;
derive a pattern waveform from the waveform using one of either hardware or software clock recovery;
extract more than one pulse response from the pattern waveform by performing linear fit pulse response (LFPR) extractions on the pattern waveform;
present one or more data representations including a data representation of the more than one pulse responses to a machine learning network to produce a measurement prediction for the DUT; and
receive the measurement prediction for the DUT from the machine learning network.

19. The test and measurement instrument as claimed in claim 18, wherein the one or more data representations comprise one or more of a vertical histogram of the whole pattern waveform, a vertical histogram at the center of a unit interval of an eye diagram representation of the pattern waveform, two vertical histograms around a center of the unit interval of the eye diagram, and a horizontal histogram at an edge of crossing levels of the eye diagram.

20. The test and measurement instrument as claimed in claim 18, wherein the machine learning network employs a neural network that handles one-dimensional data and the code that causes the one or more processors to present the one or more data representations comprises code that causes the one or more processors to present a one-dimensional data set comprising a vertical histogram at an eye center of an eye diagram representation of the waveform.

21. The test and measurement instrument as claimed in claim 18, wherein the machine learning network employs a neural network that handles two-dimensional data and the code that causes the one or more processors to present the one or more data representations comprises code that causes the one or more processors to present a two-dimensional data set comprising the extracted more than one pulse responses and at least one histogram.

22. The test and measurement instrument as claimed in claim 21, wherein the two-dimensional data includes pixels having a darkness that corresponds to one of an amplitude of the extracted pulse response and a number of hits in a histogram.

23. The test and measurement instrument as claimed in claim 18, wherein the code that causes the one or more processors to present the one or more data representations to the machine learning network causes the one or more processors to normalize the one or more data representations prior to presenting the one or more data representations to the machine learning network, and to de-normalize the prediction of the measurement received from the machine learning network.

24. The test and measurement instrument as claimed in claim 18, wherein the code that causes the one or more processors to present the one or more data representations of the more than one pulse responses to the machine learning network comprises code that causes the one or more processors to present the data representation to the machine learning network for a measurement comprising one or more of signal to noise distortion ratio (SNDR), signal to noise ratio (SNR), jitter, and transmitter dispersion eye closure quaternary (TDECQ).

25. The test and measurement instrument as claimed in claim 18, wherein the one or more processors are further configured to execute code that causes the one or more processors to train the machine learning network for a selected measurement.

26. The test and measurement instrument as claimed in claim 18, wherein the code that causes the one or more processors to extract the more than one pulse response comprises code that causes the one or more processors to extract of one of a linear fit pulse response (LFPR), impulse response, and step response.

27. The test and measurement instrument as claimed in claim 18, wherein the one or more processors are further configured to execute code that causes the one or more processors to average multiple repetitions of the pattern waveform to produce an averaged pattern waveform as the pattern waveform.
